(19) United States
(12) Patent Application Publication
(10) Pub. No.: US 2024/0419853 A1
(43) Pub. Date: Dec. 19, 2024

(54) DATA PROCESSING METHOD AND APPARATUS, DEVICE, AND COMPUTER-READABLE STORAGE MEDIUM

(71) Applicant: TENCENT TECHNOLOGY (SHENZHEN) COMPANY LIMITED, Shenzhen (CN)

(72) Inventor: Haining DU, Shenzhen (CN)

(21) Appl. No.: 18/816,692

(22) Filed: Aug. 27, 2024

Related U.S. Application Data
(63) Continuation of application No. PCT/CN2023/110114, filed on Jul. 31, 2023.

(30) Foreign Application Priority Data
Sep. 6, 2022 (CN) 202211083212.1

(51) Int. Cl. G06F 30/15; G08G 1/01; G08G 1/052

(52) U.S. Cl. CPC G06F 30/15; G08G 1/0129; G08G 1/052

(57) ABSTRACT

A data processing method includes determining a sensing coverage region with sensing data and a sensing blank region not overlapping with the sensing coverage region, and generating a first virtual simulated vehicle in the sensing blank region according to a regional position relationship. The method further includes outputting reproduced simulated driving behaviors of one or more reproduced simulated vehicles corresponding to the sensing data, and outputting, according to an automatic driving model corresponding to the sensing blank region, virtual simulated driving behaviors of one or more second virtual simulated vehicles traveling in the sensing blank region. The one or more second virtual simulated vehicles include the first virtual simulated vehicle. The method also includes outputting, according to an automatic driving model corresponding to the simulated road, predicted simulated driving behaviors of one or more third virtual simulated vehicles traveling on the simulated road.

### CROSS-REFERENCE TO RELATED APPLICATIONS

This application is a continuation of International Application No. PCT/CN2023/110114, filed on Jul. 31, 2023, which claims priority to Chinese Patent Application No. 202211083212.1, entitled “DATA PROCESSING METHOD AND APPARATUS, DEVICE, AND COMPUTER-READABLE STORAGE MEDIUM” filed with the China National Intellectual Property Administration on Sep. 6, 2022, the entire contents of both of which are incorporated by reference.

### FIELD OF THE TECHNOLOGY

This application relates to the field of Internet technologies, and in particular, to a data processing method and apparatus, a device, and a computer-readable storage medium.

### BACKGROUND OF THE DISCLOSURE

With the development of society, vehicle traffic on main roads has become more and more complex. Therefore, relevant personnel not only need to understand real-time vehicle conditions on the main roads, but also need to predict future vehicle conditions on the main roads.

Intelligent vehicle infrastructure cooperative systems (IVICS), referred to as vehicle infrastructure cooperative systems, are a development direction of an intelligent traffic system (ITS).

### SUMMARY

In accordance with the disclosure, there is provided a data processing method performed by a computer device running a driving simulation system and including determining, in the driving simulation system, a sensing coverage region with sensing data and a sensing blank region not overlapping with the sensing coverage region in a simulated road, and generating, at a simulation starting moment, a first virtual simulated vehicle in the sensing blank region according to a regional position relationship between the sensing coverage region and the sensing blank region. The method further includes, in a simulation reproduction phase after the simulation starting moment, outputting, in the sensing coverage region, reproduced simulated driving behaviors of one or more reproduced simulated vehicles corresponding to the sensing data, and outputting, in the sensing blank region according to an automatic driving model corresponding to the sensing blank region, virtual simulated driving behaviors of one or more second virtual simulated vehicles traveling in the sensing blank region. The one or more second virtual simulated vehicles include the first virtual simulated vehicle. The method also includes, in a simulation prediction phase after the simulation reproduction phase, outputting, on the simulated road according to an automatic driving model corresponding to the simulated road, predicted simulated driving behaviors of one or more third virtual simulated vehicles traveling on the simulated road to obtain a predicted traffic state of the simulated road.

Also in accordance with the disclosure, there is provided a computer device including at least one processor, and at least one memory storing at least one computer program that, when executed by the at least one processor, causes the computer device to determine, in a driving simulation system, a sensing coverage region with sensing data and a sensing blank region not overlapping with the sensing coverage region in a simulated road, and generate, at a simulation starting moment, a first virtual simulated vehicle in the sensing blank region according to a regional position relationship between the sensing coverage region and the sensing blank region. The at least one computer program, when executed by the at least one processor, further causes the computer device to, in a simulation reproduction phase after the simulation starting moment, output, in the sensing coverage region, reproduced simulated driving behaviors of one or more reproduced simulated vehicles corresponding to the sensing data, and output, in the sensing blank region according to an automatic driving model corresponding to the sensing blank region, virtual simulated driving behaviors of one or more second virtual simulated vehicles traveling in the sensing blank region. The one or more second virtual simulated vehicles include the first virtual simulated vehicle. The at least one computer program, when executed by the at least one processor, also causes the computer device to, in a simulation prediction phase after the simulation reproduction phase, output, on the simulated road according to an automatic driving model corresponding to the simulated road, predicted simulated driving behaviors of one or more third virtual simulated vehicles traveling on the simulated road to obtain a predicted traffic state of the simulated road.

Also in accordance with the disclosure, there is provided a non-transitory computer-readable storage medium storing at least one computer program that, when executed by at least one processor, causes the at least one processor to determine, in a driving simulation system, a sensing coverage region with sensing data and a sensing blank region not overlapping with the sensing coverage region in a simulated road, and generate, at a simulation starting moment, a first virtual simulated vehicle in the sensing blank region according to a regional position relationship between the sensing coverage region and the sensing blank region. The at least one computer program, when executed by the at least one processor, further causes the at least one processor to, in a simulation reproduction phase after the simulation starting moment, output, in the sensing coverage region, reproduced simulated driving behaviors of one or more reproduced simulated vehicles corresponding to the sensing data, and output, in the sensing blank region according to an automatic driving model corresponding to the sensing blank region, virtual simulated driving behaviors of one or more second virtual simulated vehicles traveling in the sensing blank region. The one or more second virtual simulated vehicles include the first virtual simulated vehicle. The at least one computer program, when executed by the at least one processor, also causes the at least one processor to, in a simulation prediction phase after the simulation reproduction phase, output, on the simulated road according to an automatic driving model corresponding to the simulated road, predicted simulated driving behaviors of one or more third virtual simulated vehicles traveling on the simulated road to obtain a predicted traffic state of the simulated road.

### BRIEF DESCRIPTION OF THE DRAWINGS

FIG. 1 is a schematic architectural diagram of a system according to an embodiment of this application.

FIG. 2 is a schematic flowchart of a data processing method according to an embodiment of this application.

FIG. 3 is a schematic diagram showing a scenario of a sensing coverage region and a sensing blank region according to an embodiment of this application.

FIG. 4A is a schematic diagram showing a scenario of generating a first virtual simulated vehicle in a sensing downstream region according to an embodiment of this application.

FIG. 4B is a schematic flowchart of a virtual simulated vehicle generation method for a sensing downstream region at a simulation starting moment according to an embodiment of this application.

FIG. 4C is a schematic diagram showing a scenario of outputting a virtual simulated driving behavior in a sensing downstream region according to an embodiment of this application.

FIG. 4D is a schematic flowchart of a virtual simulated vehicle generation method for a sensing downstream region in a simulation reproduction phase according to an embodiment of this application.

FIG. 5 is a schematic flowchart of a data processing method according to an embodiment of this application.

FIG. 6A is a schematic diagram showing a scenario of generating a first virtual simulated vehicle in a sensing upstream region according to an embodiment of this application.

FIG. 6B is a schematic flowchart of a virtual simulated vehicle generation method for a sensing upstream/midstream region at a simulation starting moment according to an embodiment of this application.

FIG. 6C is a schematic diagram showing a scenario of outputting a virtual simulated driving behavior in a sensing upstream region according to an embodiment of this application.

FIG. 6D is a schematic flowchart of a virtual simulated vehicle generation method for a sensing upstream region in a simulation reproduction phase according to an embodiment of this application.

FIG. 7 is a schematic flowchart of a predicted driving simulation behavior generation method according to an embodiment of this application.

FIG. 8 is a schematic flowchart of a data processing method according to an embodiment of this application.

FIG. 9A is a schematic diagram showing a basic traffic map according to an embodiment of this application.

FIG. 9B is a polyline example diagram showing average vehicle flow according to an embodiment of this application.

FIG. 10A is a schematic diagram showing a scenario of outputting a virtual driving simulation behavior in a sensing midstream region according to an embodiment of this application.

FIG. 10B is a schematic flowchart of a virtual simulated driving behavior generation method for a sensing midstream region in a simulation reproduction phase according to an embodiment of this application.

FIG. 11 is an example diagram showing simulation deduction of a simulated main road for “time” according to an embodiment of this application.

FIG. 12 is a schematic structural diagram of a data processing apparatus according to an embodiment of this application.

FIG. 13 is a schematic structural diagram of a computer device according to an embodiment of this application.

### DESCRIPTION OF EMBODIMENTS

The technical solutions in embodiments of this application are clearly and completely described in the following with reference to the accompanying drawings in the embodiments of this application. Apparently, the described embodiments are merely some rather than all of the embodiments of this application. All other embodiments obtained by a person of ordinary skill in the art based on the embodiments of this application without making creative efforts shall fall within the protection scope of this application.

To facilitate understanding, some terms are first briefly explained below.

A vehicle infrastructure cooperative system is a safe, efficient, and environmentally friendly road traffic system formed by using advanced wireless communication and new-generation Internet technologies to implement vehicle-vehicle and vehicle-road dynamic real-time information interaction in all aspects, and carry out vehicle active safety control and road cooperative management on the basis of full space-time dynamic traffic information collection and integration to fully achieve effective cooperation of people, vehicles, and roads, ensure traffic safety, and improve traffic efficiency. In the embodiments of this application, an IVICS may be configured to determine accurate reproduction simulation and accurate prediction simulation of simulated main roads.

A physical road may also be referred to as a road, which refers to a road in the physical world in the embodiments of this application. For example, a physical main road refers to a real main road in the physical world.

A simulated road may also be referred to as a virtual road, which is mapping of a physical road in a simulation system, for example, mapping of an environment, vehicles, incidents, and other elements of the physical road. For example, a simulated main road is mapping of a real physical main road in the physical world.

A reproduced simulated vehicle is a simulated vehicle reproduced in the simulation system according to information of a real vehicle included in sensing data collected by a sensing device on a physical road side. To be specific, the reproduced simulated vehicle is mapping of a real vehicle on a physical road, including, for example, mapping of a position, a driving behavior, and other elements of the real vehicle.

A virtual simulated vehicle is a virtual vehicle generated, for a sensing blank region without sensing data in the simulation system, in the simulation system according to historical data or a basic traffic map of the region to prevent absence of vehicles in the region at a simulation starting moment, which is configured to simulate real vehicles possibly existing in the sensing blank region.

With the research and progress of an artificial intelligence technology, the artificial intelligence technology is studied and applied in a plurality of fields such as a common smart home, a smart wearable device, a virtual assistant, a smart speaker, smart marketing, unmanned driving, automatic driving, an unmanned aerial vehicle, a robot, smart medical care, and smart customer service. It is believed that with the development of technologies, the artificial intelligence technology will be applied to more fields, and play an increasingly important role. In the embodiments of this application, artificial intelligence may be configured to generate an automatic driving model. The automatic driving model represents a comprehensive algorithm module with decision-making, planning, and control execution functions.

A digital twin is a technical means to digitally create a virtual entity of a physical entity to simulate, validate, predict, and control a whole life cycle process of the physical entity by means of historical data, real-time data, and algorithmic models. The digital twin can establish a virtual parallel world for a road, map environments, vehicles, incidents, and other elements of a physical world of the road in real time and completely, and perform full sensing and dynamic monitoring through sensor data distributed on the road to form precise information expression and mapping of the virtual road for the physical road in an information dimension, so that management personnel, even not on a road site, can still grasp a state of the entire road and solve problems such as difficulty in detection of an entire section, delayed incident discovery, and difficulty in incident review. The digital twin has a simulation capability, and also has prediction and control capabilities. In the embodiments of this application, the digital twin may be configured to generate a simulated main road and a simulation environment corresponding thereto.

In section regions that may be covered by sensors, information collected by multi-dimensional transport facilities such as video and radar is self-contained and fused. Through a target fusion algorithm, original incoherent target information obtained by various sensors can corroborate and complement each other to form basically complete target attribute information. The target attribute information may be used as the sensing data in the embodiments of this application, so accurate depiction of a traveling trajectory of a vehicle on the main road can be realized. For example, through an association relationship of a map, a target detected by the radar and a target recognized by the video are associated. At the same time, a real-time detection target is superimposed on a high-precision map to realize a connection between a physical space and a virtual space and complete holographic sensing of digital mapping. Then, the main road can be reproduced and simulated in real time in a driving simulation system, and on this basis, simulation deduction, description, diagnosis, prediction, decision-making on traffic hazards, traffic incidents, traffic congestion, and other core services are performed to achieve real-time and efficient intelligent analysis and active control and ultimately realize closed-loop control, thereby achieving refinement, intelligence, standardization, and specialization of management of the main road and laying a solid foundation for traffic management.

Since not all sections of the main road have sensing data, in the related art, only some regions with sensing data in the main road can be reproduced and simulated. Therefore, in the related art, a global condition of the main road cannot be accurately reproduced, which reduces accuracy of reproduction of the simulated main road. In addition, due to low accuracy of reproduction, accuracy of prediction of the simulated main road may be low.

In the embodiments of this application, a computer device may generate, at a simulation starting moment, a first virtual simulated vehicle in a sensing blank region according to a regional position relationship between the sensing coverage region and a sensing blank region. The sensing coverage region includes regions with sensing data in the simulated main road, and the sensing blank region includes regions not overlapping with the sensing coverage region in the simulated main road. Apparently, the sensing blank region has no sensing data. Further, in a simulation reproduction phase after the simulation starting moment, reproduced simulated driving behaviors of reproduced simulated vehicles corresponding to the sensing data are outputted in the sensing coverage region, and virtual simulated driving behaviors of one or more second virtual simulated vehicles traveling in the sensing blank region is outputted in the sensing blank region. It is clear that in the simulation reproduction phase, the sensing coverage region outputs sensing data, and the sensing blank region outputs virtual data. Further, in a simulation prediction phase after the simulation reproduction phase, a predicted simulated driving behavior of a third virtual simulated vehicle traveling on the simulated main road is outputted on the simulated main road according to an automatic driving model corresponding to the simulated main road. It is clear that in the simulation prediction phase, the sensing blank region outputs prediction data, and the sensing coverage region also outputs prediction data. As can be seen from the above, in the embodiments of this application, at the simulation starting moment and in the simulation reproduction phase, the sensing blank region without sensing data is described in terms of simulated vehicles, so accuracy of reproduction of the driving simulation system for the simulated main road can be improved. In addition, in the embodiments of this application, simulation of the simulated main road in different simulation phases is described respectively, so accuracy of prediction of the driving simulation system for the simulated main road can be improved.

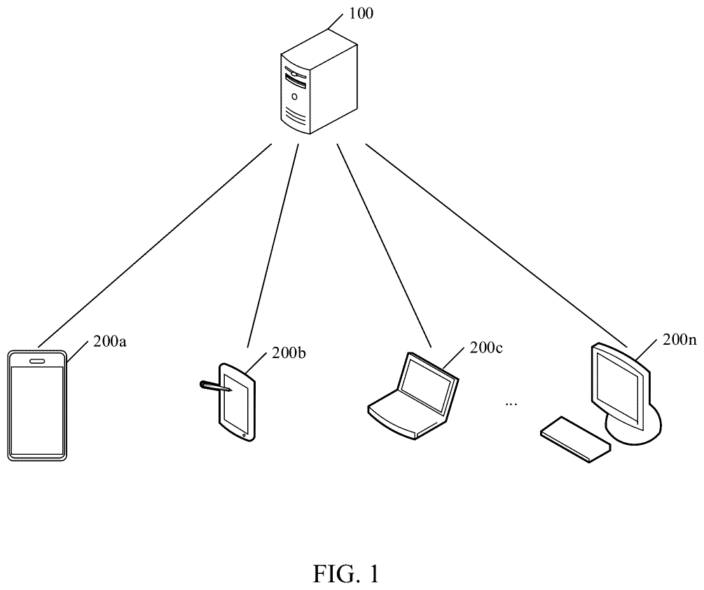

Referring to FIG. 1, FIG. 1 is a schematic architectural diagram of a system according to an embodiment of this application. As shown in FIG. 1, the system may include a service server 100 and a terminal device cluster. The terminal device cluster may include one or more terminal devices. A quantity of the terminal device is not limited in this application. As shown in FIG. 1, the terminal device cluster may include a terminal device 200a, a terminal device 200b, a terminal device 200c, . . . , and a terminal device 200n.

Communication connections may exist between the terminal devices. For example, a communication connection exists between the terminal device 200a and the terminal device 200b, and a communication connection exists between the terminal device 200a and the terminal device 200c. At the same time, any terminal device in the terminal device cluster may have a communication connection with the service server 100. For example, a communication connection exists between the terminal device 200a and the service server 100. A connection manner of the above communication connection is not limited. The communication connection may be a direct or indirect connection through wired communication, or a direct or indirect connection through wireless communication, or in other manners, which is not limited in this application.

Each terminal device in the terminal device cluster as shown in FIG. 1 may have an application client installed. The application client, when running in each terminal device, may perform data interaction with the service server 100 shown in FIG. 1 through the above communication connection. The application client may be an application client with a function of loading a simulated main road such as a video application, a live-broadcasting application, a social application, an instant messaging application, a game application, a navigation application, a map application, or a browser. The application client may be an independent client, or an embedded sub-client integrated in a client (for example, a social client, an education client, or a multimedia client), which is not limited herein.

Taking the navigation application as an example, the service server 100 may be a collection including a plurality of servers such as a back-end server and a data processing server corresponding to the navigation application. Therefore, each terminal device may perform data transmission with the service server 100 through the application client corresponding to the navigation application. For example, each terminal device may upload a road vehicle prediction request for a simulated main road to the service server 100 through the application client of the navigation application. Then, the service server 100 may perform vehicle prediction processing on the simulated main road according to the road vehicle prediction request to obtain a predicted simulated driving behavior of a virtual simulated vehicle, and returns the predicted simulated driving behavior of the virtual simulated vehicle to the terminal device.

In specific implementations of this application, when the embodiments of this application are applied to a specific product or a technology, involved related data such as user information (e.g., sensing data and historical data of the simulated main road) need to be permitted or consented by a user, and collection, use, and processing of the related data need to conform to related laws and regulations and standards in a related country or region.

To facilitate subsequent understanding and description, in the embodiments of this application, one terminal device may be selected from the terminal device cluster shown in FIG. 1 as a target terminal device. For example, the terminal device 200a is used as the target terminal device. When obtaining a road vehicle prediction request for a physical main road, the terminal device 200a may transmit the road vehicle prediction request to the service server 100. The service server 100 obtains a driving simulation system according to the road vehicle prediction request, generates a simulated main road corresponding to the physical main road in the driving simulation system, and determines a sensing coverage region with sensing data and a sensing blank region not overlapping with the sensing coverage region in the simulated main road. The sensing data may be real road data, for example, data collected by sensing devices on real main road sides, which may include driving routes of real vehicles, driving positions, obstacle objects around the real vehicles (such as obstacle vehicles, obstacle pedestrians, and obstacles), positions of the obstacle objects, and the like. Not all sections of the simulated main road have sensing data, because real road data of some sections is not collected, processed, and generated as sensing data. Therefore, before the driving simulation system operates, there is a need to determine sections with sensing data and sections without sensing data. In the embodiments of this application, in the simulated main road, the sections with sensing data are referred to as sensing coverage regions, and the sections without sensing data are referred to as sensing blank regions.

The driving simulation system includes two consecutive simulation phases. The first simulation phase is a simulation reproduction phase, and the second simulation phase is a simulation prediction phase. Since the sensing blank region has no sensing data and a real vehicle may travel on real sections mapped by the sensing blank region, the service server 100 generates, at a simulation starting moment, a first virtual simulated vehicle in the sensing blank region according to a regional position relationship between the sensing coverage region and the sensing blank region. The first virtual simulated vehicle is generated to fit an actual traffic state of the sensing blank region. Further, in a simulation reproduction phase after the simulation starting moment, the service server 100 outputs a reproduced simulated driving behavior corresponding to the sensing data in the sensing coverage region. The reproduced simulated driving behavior is consistent with an actual driving behavior in the sensing data. For example, if information in the sensing data at a certain moment is that a real vehicle a decelerates and moves to a right lane, in the driving simulation system, for the sensing coverage region, a reproduced simulated driving behavior of a reproduced simulated vehicle corresponding to the real vehicle a is to decelerate and travel to the right lane.

At the same time, the service server 100 outputs virtual simulated driving behaviors of one or more second virtual simulated vehicles in the sensing blank region. A second virtual simulated vehicle is a vehicle traveling in the sensing blank region and includes the first virtual simulated vehicle. By operating the simulation reproduction phase, the service server 100 may determine that a simulated traffic state reproduced in the driving simulation system is highly similar to an actual scenario (a simulated traffic state reproduced in the sensing coverage region is consistent with the actual scenario). Therefore, it can be ensured that initial simulation data entering the simulation prediction phase is highly similar to the actual scenario, thereby determining accuracy of the predicted simulated driving behavior outputted by the driving simulation system.

Further, in a simulation prediction phase after the simulation reproduction phase, the service server 100 stops inputting the sensing data. In this case, the driving simulation system performs predictive simulation on all sections of the simulated main road, and according to the virtual simulated driving behavior and the reproduced simulated driving behavior in the simulation reproduction phase, the service server 100 outputs a predicted simulated driving behavior of a third virtual simulated vehicle on the simulated main road.

Subsequently, the service server 100 transmits the predicted simulated driving behavior to the terminal device 200a, and the terminal device 200a, after receiving the predicted simulated driving behavior transmitted by the service server 100, may display the predicted simulated driving behavior on a screen corresponding thereto. The service server 100 may transmit the predicted simulated driving behavior to the terminal device 200a in real time. For example, for each operation by a simulation step size, a predicted simulated driving behavior corresponding to the simulation step size is transmitted to the terminal device 200a. The service server 100 may alternatively transmit the predicted simulated driving behavior to the terminal device 200s after the simulation prediction phase is over. In some embodiments, the service server 100 may transmit predicted simulated driving behaviors in an update cycle to the terminal device 200a according to the update cycle. The manner in which the service server 100 transmits the predicted simulated driving behavior is not limited in this embodiment of this application, which may be set according to a requirement of an actual application scenario.

In some embodiments, if the terminal device 200a may locally obtain the sensing data, the terminal device 200a may locally create the driving simulation system. A subsequent processing process is consistent with the process of generating the predicted simulated driving behavior by the service server 100, which is not described herein again.

The service server 100, the terminal device 200a, the terminal device 200b, the terminal device 200c, . . . , and the terminal device 200n above may all be blockchain nodes in a blockchain network. The data (e.g., the sensing data) described throughout the specification may be stored in a manner that the blockchain nodes generate blocks according to the data and add the blocks to a blockchain for storage.

The blockchain is a new application mode of computer technologies such as distributed data storage, point-to-point transmission, a consensus mechanism, and an encryption algorithm, and is mainly configured to sort data in chronological order and encrypt the data into a ledger so that the data cannot be tampered with and forged and the data can be verified, stored, and updated. The blockchain is essentially a decentralized database. Each node in the database stores a same blockchain, and the node is classified as a core node, a data node, or a light node in the blockchain network. The core node, the data node, and the light node jointly form a blockchain node. The core node is responsible for consensus of the entire blockchain network, i.e., the core node is a consensus node in the blockchain network. A process of writing transaction data into a ledger in the blockchain network may be that the data node or the light node in the blockchain network transaction data obtains the transaction data and then transmits the transaction data in the blockchain network (i.e., the nodes transmit the transaction data one by one) until the consensus node receives the transaction data, and the consensus node packs the transaction data into a block, performs a consensus on the block, and writes the transaction data into the ledger after the consensus is reached. Herein, the transaction data is illustrated with sensing data. The service server 100 (the blockchain node), after performing a consensus on the transaction data, generates blocks according to the transaction data, and stores the blocks in the blockchain network. For reading of the transaction data (i.e., the sensing data), the blockchain node may obtain the block including the transaction data from the blockchain network, and further obtain the transaction data from the block.

The method provided in this embodiment of this application may be performed by a computer device. The computer device includes, but is not limited to, a terminal device or a service server. The service server may be an independent physical server, or may be a server cluster including a plurality of physical servers or a distributed system, or may be a cloud server that provides basic cloud computing services such as a cloud database, a cloud service, cloud computing, a cloud function, cloud storage, a network service, cloud communication, a middleware service, a domain name service, a security service, a CDN, a big data, and an artificial intelligence platform. The terminal device includes, but is not limited to, a mobile phone, a computer, an intelligent voice interaction device, an intelligent appliance, a vehicle-mounted terminal, an aircraft, and the like. The terminal device and the service server may be directly or indirectly connected in a wired or wireless manner, which is not limited in the embodiments of this application.

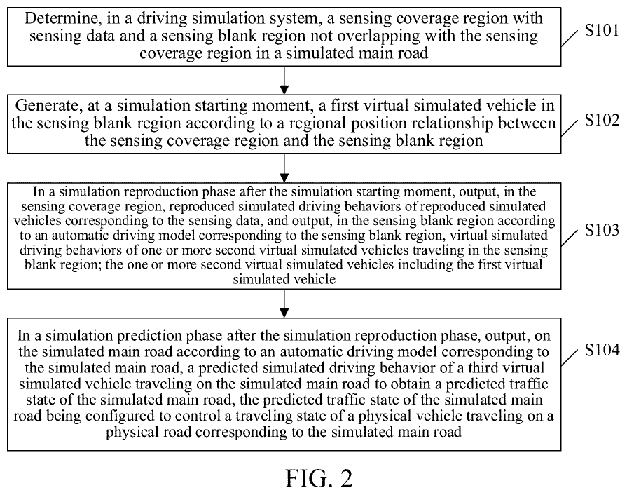

Further, Referring to FIG. 2, FIG. 2 is a schematic flowchart of a data processing method according to an embodiment of this application. This embodiment of this application may be applied to various scenarios, including, but not limited to, a cloud technology, artificial intelligence, smart transportation, assisted driving, and the like. This embodiment of this application may be applied to service scenarios such as route search scenarios, route recommendation scenarios, route navigation scenarios for main roads. Specific service scenarios will not be listed one by one herein. The data processing method may be performed by a service server (e.g., the service server 100 shown in FIG. 1 above), or performed by a terminal device (e.g., the terminal device 200a shown in FIG. 1 above), or interactively performed by the service server and the terminal device. For case of understanding, this embodiment of this application is described with an example in which the method is performed by the service server. As shown in FIG. 2, the data processing method may include at least the following operations S101 to S104.

S101: Determine, in a driving simulation system, a sensing coverage region with sensing data and a sensing blank region not overlapping with the sensing coverage region in a simulated main road. The sensing blank region is a region without sensing data in the simulated main road.

Specifically, the method proposed in this embodiment of this application may be embedded in the driving simulation system and configured to perform space-time simulation deduction on traffic vehicles on a main road in a digital twin system. Specifically, before the simulation operates, settings are made through the method in this embodiment of this application (see S102 for details), in each simulation step size after the simulation operates, space-time deduction is performed on a simulated vehicle in the driving simulation system, and motion of the simulated vehicle is described through the method (see S103 to S104 for details) in this embodiment of this application.

In this embodiment of this application, the space-time simulation deduction has two meanings. “Space” refers to motion simulation on the virtual simulated vehicle in the sensing blank region, and “time” refers to simulation on an operating state of the simulated vehicle in a future period of time after injection of the sensing data. Through the combination of “time” and “space,” real-time global conditions of a main line can be determined, and a traffic situation in a future period of time can be predicted. Then, measures can be taken in advance according to the future traffic situation, such as some proactive preventive control measures, to alleviate upcoming congestion. Deduction of the main road is described below in S102 to S104 from two aspects of “space” and “time.”

A research object in this embodiment of this application may be a digital twin system (i.e., the driving simulation system in this embodiment of this application) of the main road. Therefore, there is a need to sense and simulate vehicles traveling on the main road. In reality, sensing devices on a main road side have a certain coverage range. The coverage range is limited by types of the sensing devices (such as millimeter-wave radar and cameras), weather conditions, and the like. In this embodiment of this application, part of the main road effectively covered by the sensing devices is defined as the sensing coverage region, which can ensure that all vehicle information in this region can be collected by the sensing devices and uploaded to the driving simulation system as sensing data for the driving simulation system to perform complete mapping and reproduction of information. In this embodiment of this application, part of the main road not effectively covered by the sensing devices is defined as the sensing blank region.

The service server determines, in the driving simulation system, a physical main road that needs to be simulated, obtains a simulated main road corresponding to the physical main road in the driving simulation system, determines regions with sensing data in the simulated main road, determines the regions with sensing data to be sensing coverage regions, and determines the remaining regions (i.e., regions without sensing data) in the simulated main road except the sensing coverage regions to be sensing blank regions. Different simulated main roads have different lengths, and roadside sensing devices are different, so sensing coverage regions and sensing blank regions corresponding thereto are different. In this embodiment of this application, a quantity and a length of the sensing coverage region in the simulated main road are not limited, which are determined according to an actual application scenario. Similarly, a quantity and a length of the sensing blank region in the simulated main road are not limited, which are determined according to an actual application scenario. In this embodiment of this application, it is sufficient that a condition of at least one sensing coverage region and at least one sensing blank region is met.

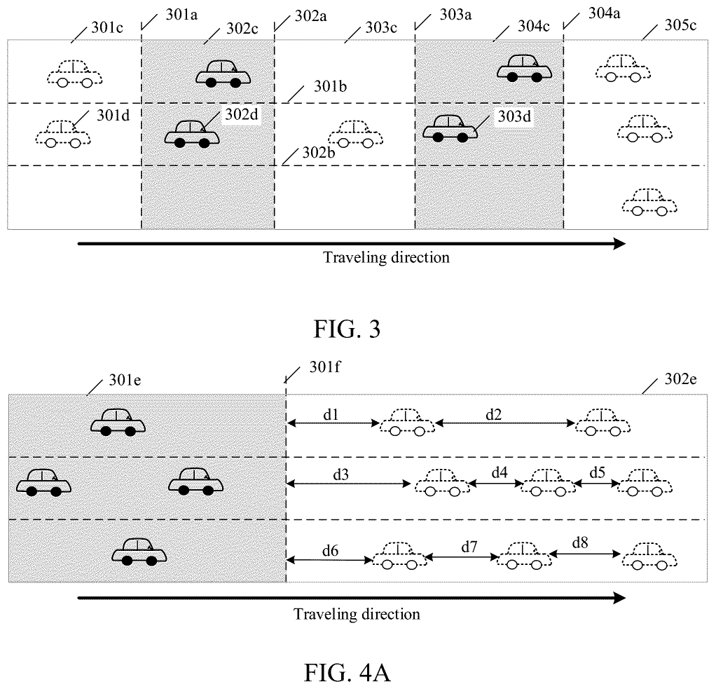

Referring to FIG. 3 together, FIG. 3 is a schematic diagram showing a scenario of a sensing coverage region and a sensing blank region according to an embodiment of this application. As shown in FIG. 3, the service server includes 3 sensing blank regions and 2 sensing coverage regions in the simulated main road generated in the driving simulation system. The 3 sensing blank regions are a sensing blank region 301c, a sensing blank region 303c, and a sensing blank region 305c respectively. The 2 sensing coverage regions are a sensing coverage region 302c and a sensing coverage region 304c respectively. Simulated vehicles in the 3 sensing blank regions may all be understood as virtual simulated vehicles. For example, a simulated vehicle 301d is a virtual simulated vehicle. When the driving simulation system has not entered the simulation prediction phase, the simulated vehicles in the 2 sensing coverage regions are generated according to the sensing data, all of which may be understood as reproduced simulated vehicles. For example, a simulated vehicle 302d is a reproduced simulated vehicle. In this embodiment of this application, for example, the simulated main road has 3 simulated lanes. A dotted line 301b and a dotted line 302b are both lane dividing lines.

The simulated main road described above is obtained by simulating a real main road, such as a main road in the digital twin system. In this scenario, the sensing data may be real road data collected by roadside sensing devices on the real main road. In addition, the example in this application does not limit real-time performance of the real road data, which may be real-time real road data or playback real road data. In some embodiments, the sensing data may be virtual road data, for example, virtual road data set by the service server to predict whether a vehicle collision may occur on the real main road. In another feasible solution, the simulated main road may alternatively be a virtual main road. In this scenario, the sensing data is virtual road data. As described above, origins of the simulated main road and the sensing data are not limited in this embodiment of this application, which may be set according to a requirement of an actual application scenario.

S102: Generate, at a simulation starting moment, a first virtual simulated vehicle in the sensing blank region according to a regional position relationship between the sensing coverage region and the sensing blank region.

Specifically, for the sensing coverage region, starting sensing data of the sensing coverage region at the simulation starting moment is obtained from the sensing data; and a starting reproduced simulated vehicle is generated in the sensing coverage region according to the starting sensing data. The starting reproduced simulated vehicle is one of the reproduced simulated vehicles corresponding to the reproduced simulated driving behaviors.

Specifically, for the sensing blank region, a starting traffic state corresponding to the sensing blank region is determined according to the regional position relationship between the sensing coverage region and the sensing blank region; and the first virtual simulated vehicle is generated in the sensing blank region according to the starting traffic state.

If a total quantity of the sensing coverage region is M, M being a positive integer, the regional position relationship between the sensing coverage region and the sensing blank region may include the following:
(1) an upstream regional relationship, i.e., the sensing blank region is located in an upstream region of all the M sensing coverage regions;
(2) a downstream regional relationship, i.e., the sensing blank region is located in a downstream region of all the M sensing coverage regions; and
(3) a midstream regional relationship, i.e., the sensing blank region is located between any two sensing coverage regions of all the M sensing coverage regions.

Then, a specific process of determining the starting traffic state corresponding to the sensing blank region according to the regional position relationship between the sensing coverage region and the sensing blank region may include the following cases:

In a first case, if a regional position relationship between the M sensing coverage regions and the sensing blank region is an upstream regional relationship or a midstream regional relationship,
a sensing coverage region contiguous with the sensing blank region and downstream of the sensing blank region is obtained from the M sensing coverage regions as a first sensing coverage region;
first starting sensing data corresponding to the first sensing coverage region is obtained;
a starting traffic state corresponding to the sensing blank region is determined according to the first starting sensing data if the first starting sensing data meets a state setting condition for the sensing blank region; and
first historical data of the sensing blank region is obtained and the starting traffic state is determined according to the first historical data if the first starting sensing data does not meet the state setting condition.

In a second case, if the regional position relationship between the M sensing coverage regions and the sensing blank region is a downstream regional relationship,
second historical data of the sensing blank region is obtained; the downstream regional relationship is configured to represent that the sensing blank region is located in a downstream region of all the M sensing coverage regions;
second starting historical data corresponding to the simulation starting moment is obtained from the second historical data and the second starting historical data is determined to be the starting traffic state corresponding to the sensing blank region if the second historical data is not a null set; and
a sensing coverage region contiguous with the sensing blank region and upstream of the sensing blank region is obtained from the M sensing coverage regions as an upstream sensing coverage region and the starting traffic state of the sensing blank region is determined according to the upstream sensing coverage region if the second historical data is a null set.

The second case, i.e., the case where the regional position relationship is a downstream regional relationship, is specifically described below. Please refer to the description of subsequent embodiments for the description of the first case.

A specific process of determining the starting traffic state of the sensing blank region according to the upstream sensing coverage region may include: obtaining, from starting sensing data of the M sensing coverage regions, second starting sensing data corresponding to the upstream sensing coverage region; determining the starting traffic state of the sensing blank region according to the second starting sensing data if the second starting sensing data meets the state setting condition for the sensing blank region; and determining the starting traffic state of the sensing blank region according to a target traffic state in a third basic traffic map corresponding to the sensing blank region if the second starting sensing data does not meet the state setting condition.

The generating the first virtual simulated vehicle in the sensing blank region according to the starting traffic state includes: determining an average inter-vehicle distance corresponding to the sensing blank region according to the starting traffic state of the sensing blank region; and generating the first virtual simulated vehicle in the sensing blank region along a traveling direction according to the average inter-vehicle distance corresponding to the sensing blank region and an upstream edge of the sensing blank region if the regional position relationship is a downstream regional relationship. The downstream regional relationship is configured to represent that the sensing blank region is located in a downstream region of all the sensing coverage regions.

Before the driving simulation system operates, for the sensing blank region without sensing data, there is a need to initialize the virtual simulated vehicle at the simulation starting moment to prevent “empty” sections without vehicles in a road network at the simulation starting moment. At the same time, the service server may obtain, from the sensing data, starting sensing data of the sensing coverage region at the simulation starting moment, and then generate a starting reproduced simulated vehicle in the sensing coverage region according to the starting sensing data. If a plurality of sensing coverage regions are provided, each sensing coverage region is processed separately. Referring to FIG. 3 again, if FIG. 3 is a schematic diagram showing a scenario at the simulation starting moment, the driving simulation system generates a starting reproduced simulated vehicle, for example, the simulated vehicle 302d illustrated in FIG. 3, in the sensing coverage region 302c according to starting sensing data corresponding to the sensing coverage region 302c. The driving simulation system generates a starting reproduced simulated vehicle, for example, a simulated vehicle 303d illustrated in FIG. 3, in the sensing coverage region 304c according to starting sensing data corresponding to the sensing coverage region 304c.

Similarly, if a plurality of sensing blank regions are provided, each sensing blank region is processed separately. As illustrated in FIG. 3, the driving simulation system processes the sensing blank region 301c, the sensing blank region 303c, and the sensing blank region 305c separately. The service server needs to generate the first virtual simulated vehicle in the sensing blank region according to the regional position relationship between the sensing coverage region and the sensing blank region. Referring to FIG. 3 again, the sensing blank region 301c is located most upstream of the simulated main road. In other words, the sensing blank region 301c is an upstream region of all the sensing coverage regions. Therefore, a regional position relationship between the sensing blank region 301c and the sensing coverage region is an upstream regional relationship. To be distinguished from other sensing blank regions, the sensing blank region in the upstream regional relationship is referred to as a sensing upstream region in this embodiment of this application.

The sensing blank region 303c is located between the sensing coverage region 302c and the sensing coverage region 303c. Therefore, a regional position relationship between the sensing blank region 303c and the sensing coverage region is a midstream regional relationship. To be distinguished from other sensing blank regions, the sensing blank region in the midstream regional relationship is referred to as a sensing midstream region in this embodiment of this application. The sensing blank region 305c is located most downstream of the simulated main road. In other words, the sensing blank region 305c is a downstream region of all the sensing coverage regions. Therefore, a regional position relationship between the sensing blank region 305c and the sensing coverage region is a downstream regional relationship. To be distinguished from other sensing blank regions, the sensing blank region in the downstream regional relationship is referred to as a sensing downstream region in this embodiment of this application.

A boundary between the sensing coverage region and the sensing upstream region (i.e., a downstream edge of the sensing upstream region and an upstream edge of the sensing coverage region) may be defined as a sensing upper boundary, for example, a sensing upper boundary 301a in FIG. 3. A boundary between the sensing coverage region and the sensing downstream region (i.e., an upstream edge of the sensing downstream region and a downstream edge of the sensing coverage region) may be defined as a sensing lower boundary, for example, a sensing lower boundary 304a in FIG. 3. An upstream edge of the sensing midstream region may be defined as a sensing lower boundary. For example, an upstream edge of the sensing blank region 303c in FIG. 3 may be defined as a sensing lower boundary 302a. A downstream edge of the sensing midstream region may be defined as a sensing upper boundary. For example, a downstream edge of the sensing blank region 303c in FIG. 3 may be defined as a sensing upper boundary 303a.

The sensing upper boundary and the sensing lower boundary in the simulated main road are line segments perpendicular to a lane direction (i.e., a traveling direction) under a reference line coordinate system (referred to as an ST coordinate system). Simulation performed in the sensing coverage region is defined as reproduced simulation. To be specific, sensed vehicle information is completely restored to the driving simulation system in real time. For the sensing blank region (including the sensing upstream region, the sensing midstream region, and the sensing downstream region above), spatial virtual simulation needs to be performed according to the following method.

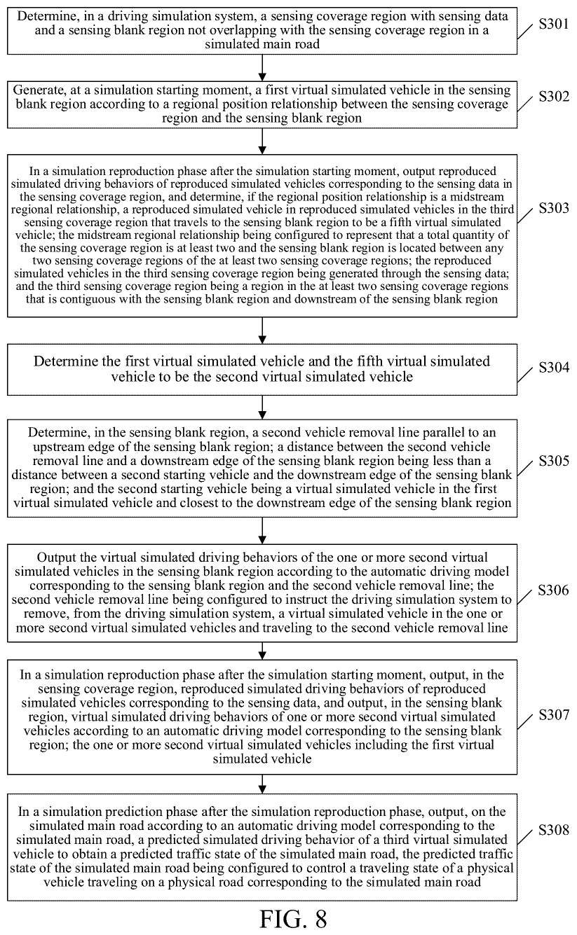

If the regional position relationship between the sensing coverage region and the sensing blank region is a downstream regional relationship, the service server obtains second historical data of the sensing blank region. An origin of the second historical data is not described in this operation. Please refer to the description in an embodiment corresponding to FIG. 8 below. In a scenario where the second historical data is not a null set, the service server fetches, from the second historical data, historical data corresponding to the simulation starting moment as second starting historical data. The service server takes the second starting historical data as the starting traffic state corresponding to the sensing blank region. The starting traffic state includes starting vehicle density, starting vehicle flow, and a starting vehicle speed. According to the starting vehicle density, the service server may determine an average inter-vehicle distance D1 corresponding to the sensing blank region, i.e., a distance between two vehicles. Further, the service server generates a normal distribution N(D1, σ²) with the average inter-vehicle distance D1 as a mean. Specific distribution and variance are not limited in this embodiment of this application, as long as diversity is ensured.

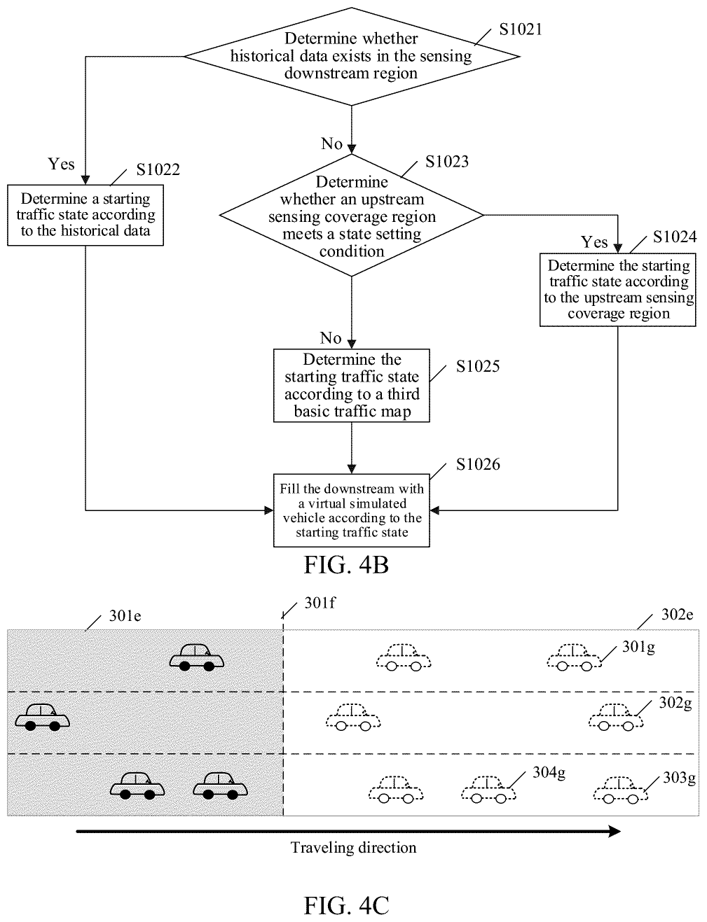

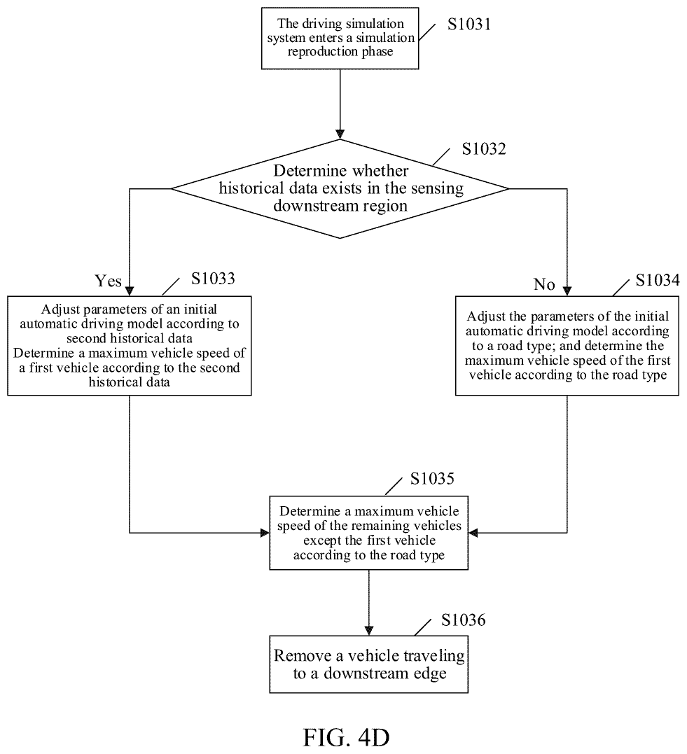

Further, referring to FIG. 4A together, FIG. 4A is a schematic diagram showing a scenario of generating a first virtual simulated vehicle in a sensing downstream region according to an embodiment of this application. As illustrated in FIG. 4A, the simulated main road includes a sensing coverage region 301e and a sensing blank region 302e. A starting reproduced simulated vehicle in the sensing coverage region 301e is reproduced according to starting sensing data corresponding to the sensing coverage region 301e. A starting traffic state of the starting reproduced simulated vehicle is also determined according to the starting sensing data corresponding to the sensing coverage region 301e. The service server starts to look for a distance di (a random value conforming to the normal distribution N(D1, σ²)) downstream (i.e., the traveling direction) at a sensing lower boundary 301f (i.e., an upstream edge) of the sensing blank region 302e (which may also be referred to as the sensing downstream region) as a position of a virtual simulated vehicle with which the sensing downstream region needs to be filled, and sequentially generates inter-vehicle distances dj (j=i, i+1, . . . ) to fill the downstream with virtual simulated vehicles, for example, an inter-vehicle distance d1 to an inter-vehicle distance d8 illustrated in FIG. 4A. A filling sequence is not limited in this embodiment of this application. The filling may be performed in order of lanes. To be specific, one lane is first filled and then another lane is filled, or several lanes close to the sensing upper boundary 301f may be first filled, for example, 3 lanes illustrated in FIG. 4A, and then downstream backtracking is performed. When one selected inter-vehicle distance dj extends downstream and exceeds a range of the sensing downstream region (i.e., a downstream edge of the sensing downstream region), the service server determines that initialization of the sensing downstream region in this lane has been completed.

If the second historical data is a null set, the service server determines a sensing coverage region contiguous with the sensing downstream region and upstream of the sensing downstream region to be an upstream sensing coverage region, and determines a starting traffic state of the sensing downstream region according to the upstream sensing coverage region. As illustrated in FIG. 3, the sensing coverage region 304c may be used as an upstream sensing coverage region of the sensing blank region 305c. As illustrated in FIG. 4A, the sensing coverage region 301e may be used as an upstream sensing coverage region of the sensing blank region 302c.

If more than one starting reproduced simulated vehicle is in a simulated lane in the upstream sensing coverage region, the service server determines that the upstream sensing coverage region meets a state setting condition for the sensing downstream region. If there is only one starting reproduced simulated vehicle or no starting reproduced simulated vehicle in all simulated lanes in the upstream sensing coverage region, the service server determines that the upstream sensing coverage region does not meet the state setting condition for the sensing downstream region.

When the upstream sensing coverage region meets the state setting condition for the sensing downstream region, the service server calculates an inter-vehicle distance between each two simulated vehicles in the simulated lane and then determines an average inter-vehicle distance corresponding to the simulated lane. According to the inter-vehicle distance corresponding to each simulated lane, the service server may determine an average inter-vehicle distance D2 corresponding to the sensing downstream region to generate a normal distribution N(D2, σ²) with D2 as a mean. A process in which the service server fills the sensing downstream region with virtual simulated vehicles according to the normal distribution N(D2, σ²) is the same as the process in which the sensing downstream region is filled with virtual simulated vehicles according to the normal distribution N(D1, σ²), and therefore is not described herein. Please refer to the description above.

If the upstream sensing coverage region does not meet the state setting condition for the sensing downstream region and the second historical data of the sensing downstream region is a null set, the service server randomly selects, according to a basic traffic map (i.e., the third basic traffic map above) corresponding to the sensing downstream region, a vehicle density in a free traveling state (i.e., the target traffic state above) in the third basic traffic map. According to the vehicle density, the service server determines an average inter-vehicle distance D3, and the following process is the same as the process in which the service server fills the sensing downstream region with a virtual simulated vehicle (i.e., the first virtual simulated vehicle) according to the average inter-vehicle distance D1, and therefore is not described herein. Please refer to the description above. The basic traffic map is not described in this operation. Please refer to the description of the basic traffic map in the embodiment corresponding to FIG. 8 below.

A processing process in this operation may be obtained with reference to FIG. 4B together. FIG. 4B is a schematic flowchart of a virtual simulated vehicle generation method for a sensing downstream region at a simulation starting moment according to an embodiment of this application. As shown in FIG. 4B, the method may include the following operations:

S1021: The service server determines whether historical data exists in the sensing downstream region. Specifically, historical data corresponding to the sensing downstream region is defined as second historical data in this embodiment of this application. When historical data exists in the sensing downstream region, the service server performs S1022. When historical data does not exist in the sensing downstream region, the service server performs S1023.

S1022: The service server determines a starting traffic state according to the historical data, and performs S1026.

S1023: The service server determines whether an upstream sensing coverage region meets a state setting condition. If the upstream sensing coverage region meets the state setting condition, the service server performs S1024. If the upstream sensing coverage region does not meet the state setting condition, the service server performs S1025.

S1024: The service server determines the starting traffic state according to the upstream sensing coverage region, and performs S1026.

S1025: The service server determines the starting traffic state according to a third basic traffic map, and performs S1026.

S1026: The service server fills the downstream with a virtual simulated vehicle according to the starting traffic state. In this embodiment of this application, a virtual simulated vehicle generated at the simulation starting moment is defined as a first virtual simulated vehicle.

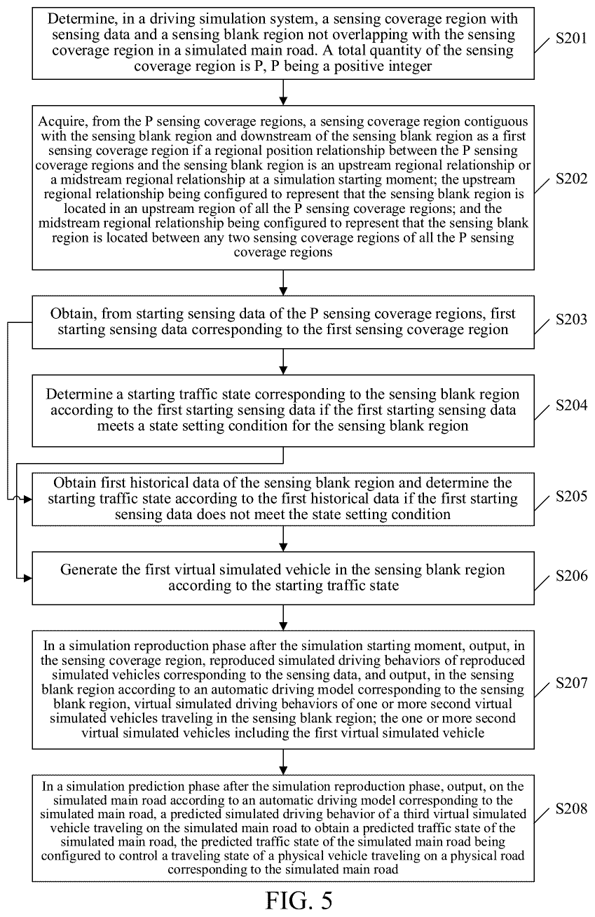

A scenario where the regional position relationship is an upstream regional relationship and a scenario where the regional position relationship is a midstream regional relationship are not described in this operation. Please refer to the description in an embodiment corresponding to FIG. 5 below and the description in the embodiment corresponding to FIG. 8 below.

S103: In a simulation reproduction phase after the simulation starting moment, output, in the sensing coverage region, reproduced simulated driving behaviors of reproduced simulated vehicles corresponding to the sensing data, and output, in the sensing blank region according to an automatic driving model corresponding to the sensing blank region, virtual simulated driving behaviors of one or more second virtual simulated vehicles traveling in the sensing blank region; the one or more second virtual simulated vehicles including the first virtual simulated vehicle.

Specifically, when the regional position relationship is a downstream regional relationship, a reproduced simulated vehicle in reproduced simulated vehicles in an upstream sensing coverage region that travels to the sensing blank region is determined to be a sixth virtual simulated vehicle; the reproduced simulated vehicles in the upstream sensing coverage region being generated through the sensing data; the upstream sensing coverage region being a region in the sensing coverage regions that is contiguous with the sensing blank region and upstream of the sensing blank region; the first virtual simulated vehicle and the sixth virtual simulated vehicle are determined to be the second virtual simulated vehicles; and the virtual simulated driving behaviors of the one or more second virtual simulated vehicles are outputted in the sensing blank region according to the automatic driving model corresponding to the sensing blank region and a downstream edge of the sensing blank region; the downstream edge of the sensing blank region being configured to instruct the driving simulation system to remove, from the driving simulation system, a virtual simulated vehicle in the one or more second virtual simulated vehicles and traveling to the downstream edge of the sensing blank region.

After the driving simulation system starts operating, the service server inputs the sensing data into the driving simulation system. The driving simulation system outputs, in real time according to the sensing data, a reproduced simulated vehicle in the sensing coverage region and a vehicle trajectory of the reproduced simulated vehicle, i.e., a reproduced simulated driving behavior, and reproduces a type, a position, a speed, an attitude (direction angle), and other states of the vehicle in real time in the sensing coverage region. With continuous advancing of a simulation clock, the sensing data is continuously injected into the driving simulation system. The driving simulation system reproduces simulated vehicles with reproduced simulated driving behaviors one by one in the sensing coverage region.

For the sensing blank region, to maintain authenticity of a simulation effect, the service server updates, for operation of the virtual simulated vehicle in the sensing blank region, a longitudinal speed and a transverse speed through an automatic driving model (including a following model and a lane changing model) corresponding to each sensing blank region for simulation. For the sensing blank region, the service server processes the sensing blank region with an upstream regional relationship (i.e., the sensing upstream region), the sensing blank region with a midstream regional relationship (i.e., the sensing midstream region), and the sensing blank region with a downstream regional relationship (i.e., the sensing downstream region) respectively.

At the simulation starting moment, an initial vehicle for filling, for example, the first virtual simulated vehicle as described in S102 above, exists in the sensing downstream region. After the driving simulation system starts operating, the virtual simulated vehicle in the sensing downstream region may simulate longitudinal and transverse driving behaviors of the virtual simulated vehicle in the region through an automatic driving model (including a following model and a lane changing model) corresponding to the sensing downstream region. To be distinguished from automatic driving models corresponding to other sensing blank regions, the automatic driving model corresponding to the sensing downstream region is defined as a downstream automatic driving model in this embodiment of this application.

For the sensing downstream region, as the name suggests, a sensing coverage region exists upstream thereof. Referring to FIG. 4C together, FIG. 4C is a schematic diagram showing a scenario of outputting a virtual simulated driving behavior in a sensing downstream region according to an embodiment of this application. As shown in FIG. 4C, the simulated main road includes a sensing coverage region 301e and a sensing blank region 302e. In this case, the sensing blank region 302e may be referred to as a sensing downstream region, and the sensing coverage region 301e may be referred to as an upstream sensing coverage region of the sensing downstream region. A reproduced simulated vehicle in the sensing coverage region 301e and a reproduced simulated driving behavior outputted are both determined by the sensing data. A virtual simulated driving behavior of a virtual simulated vehicle in the sensing downstream region is determined by the downstream automatic driving model.

The reproduced simulated vehicle generated in the sensing coverage region 301c becomes a virtual simulated vehicle (because there is no sensing data) after crossing the sensing lower boundary 301f and entering the sensing downstream region. In this case, like the first virtual simulated vehicle, the reproduced simulated vehicle crossing the sensing lower boundary 301f also simulates a longitudinal virtual simulated driving behavior through the following model in the downstream automatic driving model, and similarly, also simulates a transverse virtual simulated driving behavior through the lane changing model in the downstream automatic driving model. A type of the downstream automatic driving model is not limited in this embodiment of this application. It is clear that the virtual simulated vehicle in the sensing downstream region may include a virtual simulated vehicle generated at the simulation starting moment and also include a reproduced simulated vehicle traveling into the upstream sensing coverage region.

If historical data (i.e., the above second historical data) exists in the sensing downstream region, the service server adjusts parameters of an initial downstream automatic driving model according to the second historical data to obtain the above downstream automatic driving model. If no historical data exists in the sensing downstream region, the service server adjusts the parameters of the initial downstream automatic driving model according to a road type (e.g., a highway main road or an urban main road) corresponding to the sensing blank region to obtain the above downstream automatic driving model.

To ensure rationality of a traffic state, the service server needs to limit a maximum vehicle speed of a virtual simulated vehicle (which may also be referred to as a first vehicle) closest to the downstream edge in each lane in the sensing downstream region. Referring to FIG. 4C again, the first vehicle in the sensing downstream region includes a virtual simulated vehicle 301g, a virtual simulated vehicle 302g, and a virtual simulated vehicle 303g. If historical data (i.e., the above second historical data) exists in the sensing downstream region, the service server determines an average speed corresponding to the simulation reproduction phase (e.g., 5 p.m. to 5:30 p.m.) in the second historical data to be the maximum vehicle speed of the first vehicle in each lane in the sensing downstream region. The first vehicle in the downstream region may be removed from the driving simulation system when traveling to the downstream edge, and an upstream vehicle in a same lane thereof may become a new first vehicle in the lane. For example, when the virtual simulated vehicle 303g is removed from the driving simulation system, the virtual simulated vehicle 304g becomes a new first vehicle in a simulated lane thereof. If the second historical data does not exist, the service server may set the maximum vehicle speed of the first vehicle through a road type or a road speed limit. In addition, the service server determines, according to a road type or a road speed limit of the sensing downstream region, a maximum vehicle speed of the remaining virtual simulated vehicles in the sensing downstream region except the first vehicle.

A processing process of this operation may be obtained with reference to FIG. 4D together. FIG. 4D is a schematic flowchart of a virtual simulated vehicle generation method for a sensing downstream region in a simulation reproduction phase according to an embodiment of this application. As shown in FIG. 4D, the method may include the following operations:

S1031: The driving simulation system enters a simulation reproduction phase.

S1032: The service server determines whether historical data, i.e., second historical data, exists in the sensing downstream region. If the second historical data exists, S1033 is performed. If the second historical data does not exist, S1034 is performed.

S1033: The service server adjusts parameters of an initial automatic driving model (which refers to the initial downstream automatic driving model herein; the following operations in FIG. 4D are understood in a same manner) according to the second historical data, and determines a maximum vehicle speed of a first vehicle according to the second historical data.

S1034: The service server adjusts the parameters of the initial automatic driving model according to a road type; and determines the maximum vehicle speed of the first vehicle according to the road type.

S1035: The service server determines a maximum vehicle speed of the remaining vehicles except the first vehicle according to the road type.

S1036: The service server removes, i.e., deletes, a vehicle traveling to a downstream edge.

A scenario where the regional position relationship is an upstream regional relationship and a scenario where the regional position relationship is a midstream regional relationship are not described in this operation. Please refer to the description in the embodiment corresponding to FIG. 5 below and the description in the embodiment corresponding to FIG. 8 below.

S104: In a simulation prediction phase after the simulation reproduction phase, output, on the simulated main road according to an automatic driving model corresponding to the simulated main road, a predicted simulated driving behavior of a third virtual simulated vehicle traveling on the simulated main road to obtain a predicted traffic state of the simulated main road, the predicted traffic state of the simulated main road being configured to control a traveling state of a physical vehicle traveling on a physical road corresponding to the simulated main road.

Specifically, a virtual simulated vehicle in the one or more second virtual simulated vehicles and meeting a simulation prediction condition is determined to be a seventh virtual simulated vehicle; a reproduced simulated vehicle in the reproduced simulated vehicles that meets the simulation prediction condition is determined to be a target reproduced simulated vehicle; the target reproduced simulated vehicle being generated according to the sensing data; according to fourth historical data in a sensing region to which a second vehicle generation sub-region in the simulated main road belongs, an eighth virtual simulated vehicle is generated in the second vehicle generation sub-region; the second vehicle generation sub-region being located at an upstream edge of the simulated main road, and the sensing region to which the second vehicle generation sub-region belongs belonging to the sensing coverage region or the sensing blank region; the seventh virtual simulated vehicle, the target reproduced simulated vehicle, and the eighth virtual simulated vehicle are determined to be the third virtual simulated vehicle; and the predicted simulated driving behavior of the third virtual simulated vehicle is outputted on the simulated main road according to an automatic driving model corresponding to the simulated main road and a downstream edge of the simulated main road; the downstream edge of the simulated main road being configured to instruct the driving simulation system to remove, from the driving simulation system, a virtual simulated vehicle in the third virtual simulated vehicle and traveling to the downstream edge of the simulated main road.

In some embodiments, the method further includes: determining the second vehicle generation sub-region in the simulated main road according to the upstream edge of the simulated main road, a specific process of which includes:
determining, if the upstream edge of the simulated main road belongs to the sensing blank region, a first vehicle generation sub-region corresponding to the sensing blank region to be the second vehicle generation sub-region of the simulated main road; the first vehicle generation sub-region being configured to generate, in the simulation reproduction phase, a virtual simulated vehicle that is one of the one or more second virtual simulated vehicles; and
determining the second vehicle generation sub-region in the simulated main road according to the upstream edge of the simulated main road and a vehicle generation line in the simulated main road if the upstream edge of the simulated main road belongs to the sensing coverage region; the vehicle generation line in the simulated main road being perpendicular to a traveling direction of the simulated main road.

A specific process of generating, according to fourth historical data in a sensing region to which a second vehicle generation sub-region belongs, an eighth virtual simulated vehicle in the second vehicle generation sub-region may include:
obtaining predicted historical data from the fourth historical data and generating the eighth virtual simulated vehicle in the second vehicle generation sub-region according to the predicted historical data if the fourth historical data in the sensing region to which the second vehicle generation sub-region belongs is not a null set;
generating the eighth virtual simulated vehicle in the second vehicle generation sub-region according to a target traffic state in a fifth basic traffic map corresponding to the sensing region to which the second vehicle generation sub-region belongs if the fourth historical data is a null set and the sensing region to which the second vehicle generation sub-region belongs belongs to the sensing blank region; and
generating the eighth virtual simulated vehicle in the second vehicle generation sub-region according to the sensing data if the fourth historical data is a null set and the sensing region to which the second vehicle generation sub-region belongs to the sensing coverage region.

S104 may further include: determining a virtual simulated vehicle in the third virtual simulated vehicle and closest to the downstream edge of the simulated main road to be a second downstream vehicle (i.e., a first vehicle) on the simulated main road; determining a maximum vehicle speed of the second downstream vehicle according to fifth historical data in a sensing region to which the second downstream vehicle belongs; the sensing region to which the second downstream vehicle belongs belonging to the sensing blank region or the sensing coverage region; determining a virtual simulated vehicle in the third virtual simulated vehicle except the second downstream vehicle to be a third upstream vehicle; and determining a maximum vehicle speed of the third upstream vehicle according to a road type corresponding to a sensing region to which the third upstream vehicle belongs. Then, a specific process of outputting the predicted simulated driving behavior of the third virtual simulated vehicle on the simulated main road according to an automatic driving model corresponding to the simulated main road and a downstream edge of the simulated main road may include: outputting the predicted simulated driving behavior of the third virtual simulated vehicle on the simulated main road according to the automatic driving model corresponding to the simulated main road, the downstream edge of the simulated main road, the maximum vehicle speed of the third upstream vehicle, and the maximum vehicle speed of the second downstream vehicle.

The simulation prediction condition in this embodiment of this application is as follows: At the end of the simulation reproduction phase, the virtual simulated vehicle in the sensing blank region is located in an upstream region of a vehicle removal line in the sensing blank region. If the sensing blank region is a sensing upstream region, the vehicle removal line corresponding thereto is a first vehicle removal line described below. If the sensing blank region is a sensing midstream region, the vehicle removal line corresponding thereto is a second vehicle removal line described below. If the sensing blank region is a sensing downstream region, the vehicle removal line corresponding thereto is a downstream edge corresponding thereto. At the end of the simulation reproduction phase, the reproduced simulated vehicle in the sensing coverage region is located in an upstream region of a vehicle removal line in a sensing blank region contiguous with the sensing coverage region and downstream of the sensing coverage region. The simulation prediction condition may alternatively be understood as that the vehicle is not removed from the driving simulation system at the end of the simulation reproduction phase.

In a digital twin driving simulation system, a vehicle in the sensing coverage region can be digitized and be presented in real time in the driving simulation system. In this embodiment of this application, firstly, traffic vehicles that may exist in the sensing blank region are initially set to obtain the first virtual simulated vehicle. After the simulation starts operating, traveling of a vehicle on the main line is described, so that operation of the simulated vehicle maintains continuity of the traffic state in time and space on the premise of complying with traffic operation rules. On this basis, in this embodiment of this application, after injection of the sensing data stops, space-time deduction prediction of the traffic state of the simulated main road is performed, thereby realizing interactive integration of a physical space and a digital space. Therefore, a decision-making basis can be better provided.

As can be seen from the above, in this embodiment of this application, at the simulation starting moment and in the simulation reproduction phase, the sensing blank region without sensing data is described in terms of simulated vehicles, so accuracy of reproduction of the driving simulation system for the simulated main road can be improved. In addition, in this embodiment of this application, simulation of the simulated main road in different simulation phases is described respectively, so accuracy of prediction of the driving simulation system for the simulated main road can be improved.

Referring to FIG. 5, FIG. 5 is a schematic flowchart of a data processing method according to an embodiment of this application. The method may be performed by a service server (e.g., the service server 100 shown in FIG. 1 above), or performed by a terminal device (e.g., the terminal device 200a shown in FIG. 1 above), or interactively performed by the service server and the terminal device. For case of understanding, this embodiment of this application is described with an example in which the method is performed by the service server. As shown in FIG. 5, the method may include at least the following operations.

S201: Determine, in a driving simulation system, a sensing coverage region with sensing data and a sensing blank region not overlapping with the sensing coverage region in a simulated main road. A total quantity of the sensing coverage region is P, P being a positive integer.

Specifically, for example, a real main road a includes a first section and a second section. The first section has a sensing device. Therefore, the sensing device can collect real vehicle information of the first section, which is used as sensing data of a sensing coverage region corresponding to the first section in the driving simulation system. However, the second section has no sensing device. Therefore, real vehicle information of the second section cannot be collected, and then a sensing blank region corresponding to the second section in the driving simulation system has no sensing data.

S202: Obtain, from the P sensing coverage regions, a sensing coverage region contiguous with the sensing blank region and downstream of the sensing blank region as a first sensing coverage region if a regional position relationship between the P sensing coverage regions and the sensing blank region is an upstream regional relationship or a midstream regional relationship at a simulation starting moment; the upstream regional relationship being configured to represent that the sensing blank region is located in an upstream region of all the P sensing coverage regions; and the midstream regional relationship being configured to represent that the sensing blank region is located between any two sensing coverage regions of all the P sensing coverage regions.

Specifically, a scenario where the regional position relationship is a downstream regional relationship may be obtained with reference to the description of S102 in the embodiment corresponding to FIG. 2 above. This operation is configured to describe the upstream regional relationship and the midstream regional relationship.

Referring to FIG. 3 again, the sensing blank region 301c is located upstream of all the sensing coverage regions (including the sensing coverage region 302c and the sensing coverage region 304c). Therefore, a regional position relationship between the sensing blank region 301c and the sensing coverage region is an upstream regional relationship. Therefore, the sensing blank region 301c may be referred to as a sensing upstream region. In this case, the sensing coverage region 302c may be referred to as a first sensing coverage region of the sensing upstream region.

The sensing blank region 303c is located between the sensing coverage region 302c and the sensing coverage region 304c. Therefore, a regional position relationship between the sensing blank region 303c and the sensing coverage region is a midstream regional relationship. Therefore, the sensing blank region 303c may be referred to as a sensing midstream region. In this case, the sensing coverage region 304c may be referred to as a first sensing coverage region of the sensing midstream region.

S203: Obtain, from starting sensing data of the P sensing coverage regions, first starting sensing data corresponding to the first sensing coverage region.

In this disclosure, the first sensing coverage region, and the second and third sensing coverage region described below, can also be referred to as a “first target sensing coverage region,” a “second target sensing coverage region,” and a “third target sensing coverage region,” respectively, or each be simply referred to as a “target sensing coverage region.” Correspondingly, the first starting sensing data, and second starting sensing data described below, can also be referred to as “first target starting sensing data” and “second target starting sensing data,” respectively, or each be simply referred to as “target starting sensing data.”

Specifically, the first sensing coverage region includes A simulated lanes. A is a positive integer. The A simulated lanes include a simulated lane E_{F}, f being a positive integer and f being less than or equal to A.

A quantity of a reproduced simulated vehicle G_{F} in the simulated lane E_{f} is obtained from the first starting sensing data. The reproduced simulated vehicle G_{f} is a starting reproduced simulated vehicle. It is determined that the first starting sensing data meets the state setting condition if a total quantity of the reproduced simulated vehicle G_{f} is at least two. It is determined that the simulated lane E_{f} is a simulated blank lane if the total quantity of the reproduced simulated vehicle G_{f} is less than or equal to 1.

It is determined that the first starting sensing data does not meet the state setting condition if each of the A simulated lanes is a simulated blank lane.

S204: Determine a starting traffic state corresponding to the sensing blank region according to the first starting sensing data if the first starting sensing data meets a state setting condition for the sensing blank region.

For each simulated lane in the first sensing coverage region, an average inter-vehicle distance corresponding to the simulated lane is determined. Specifically, for each simulated lane E_{f}: an inter-vehicle distance of each two adjacent reproduced simulated vehicles in the at least two reproduced simulated vehicles G_{f} is determined; an average inter-vehicle distance of the at least two reproduced simulated vehicles G_{f} according to the inter-vehicle distance of each two adjacent reproduced simulated vehicles; and the average inter-vehicle distance of the at least two reproduced simulated vehicles G_{f} is determined to be the average inter-vehicle distance corresponding to the simulated lane E_{f}.

Then, vehicle density corresponding to the sensing blank region is determined according to the average inter-vehicle distances respectively corresponding to all the A simulated lanes in the first sensing coverage region; and the starting traffic state corresponding to the sensing blank region is determined according to the vehicle density and a first basic traffic map corresponding to the first sensing coverage region.

When the first sensing coverage region meets the state setting condition for the sensing blank region, the service server calculates an inter-vehicle distance between each two reproduced simulated vehicles on a simulated lane and then determines an average inter-vehicle distance corresponding to the simulated lane. The service server may determine an average inter-vehicle distance D4 corresponding to the first sensing coverage region according to an average inter-vehicle distance corresponding to each simulated lane. The service server may determine vehicle density corresponding to the first sensing coverage region according to the average inter-vehicle distance D4. The service server may determine a traffic state corresponding to the first sensing coverage region through the preset first basic traffic map corresponding to the first sensing coverage region. Herein, it is considered that the traffic state is also applicable to the sensing upstream region or the sensing midstream region. Therefore, the service server determines the traffic state corresponding to the first sensing coverage region to be the starting traffic state corresponding to the sensing blank region.

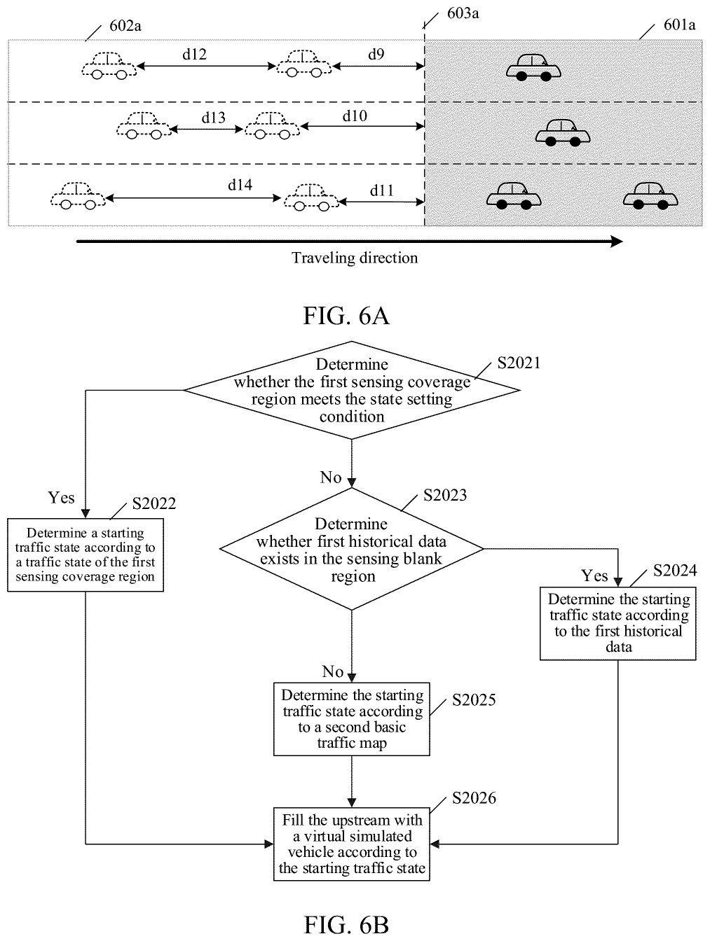

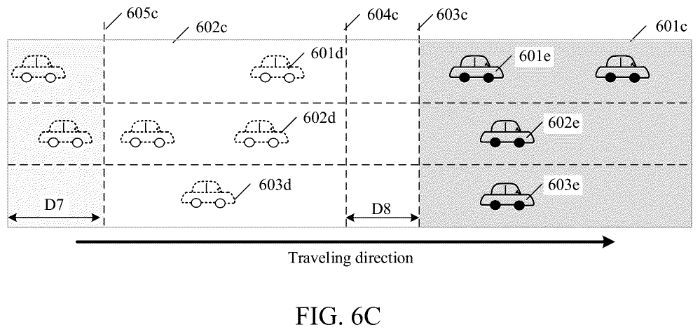

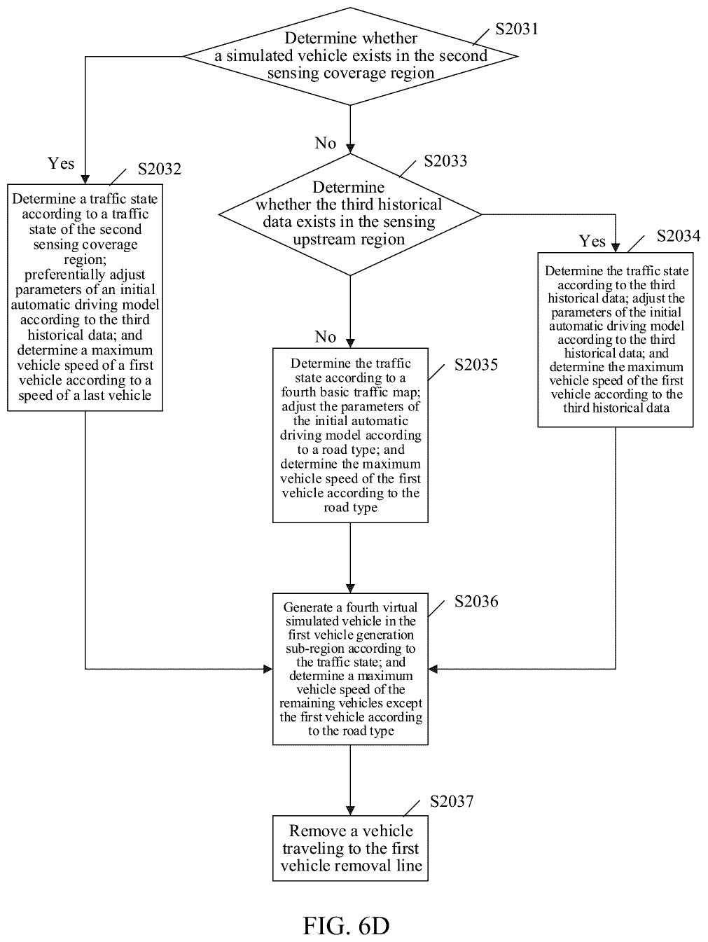

Further, the service server generates a normal distribution N(D4, σ²) with D4 as a mean. Specific distribution and variance are not limited in this embodiment of this application, as long as diversity is ensured. Referring to FIG. 6A together, FIG. 6A is a schematic diagram showing a scenario of generating a first virtual simulated vehicle in a sensing upstream region according to an embodiment of this application. As shown in FIG. 6A, the simulated main road includes a sensing blank region 602a and a sensing coverage region 601a. A starting reproduced simulated vehicle in the sensing coverage region 601a is reproduced according to starting sensing data corresponding to the sensing coverage region 601a. A starting traffic state of the starting reproduced simulated vehicle is also determined according to the starting sensing data corresponding to the sensing coverage region 601a. The service server starts to backtrack a distance di (a random value conforming to the normal distribution N(D4, σ²)) upstream (i.e., a direction opposite to the traveling direction) at a sensing upper boundary 603a (i.e., an upstream edge) of the sensing blank region 602a (which may also be referred to as the sensing upstream region) as a position of a virtual vehicle with which the sensing upstream region needs to be filled, and sequentially generates inter-vehicle distances dj (j=i, i+1, . . . ) to fill the upstream with vehicles, for example, an inter-vehicle distance d9 to an inter-vehicle distance d14 illustrated in FIG. 6A. A vehicle filling sequence is not limited in this embodiment of this application. The filling may be performed in order of lanes. To be specific, one lane is first filled and then another lane is filled, or several lanes close to the sensing upper boundary 603a may be first filled and then upstream backtracking is performed. After one selected dj backtracks upstream and exceeds a range of the sensing upstream region, the service server determines that initialization of the sensing upstream region in this lane has been completed.

Since a process of generating the first virtual simulated vehicle in the sensing upstream region is the same as the process of generating the first virtual simulated vehicle in the sensing midstream region, only the processing process of the sensing upstream region is described in S205 to S206. Please refer to the description of the sensing upstream region for the processing process of the sensing midstream region.

S205: Obtain first historical data of the sensing blank region and determine the starting traffic state according to the first historical data if the first starting sensing data does not meet the state setting condition.

Specifically, first starting historical data corresponding to the simulation starting moment is obtained from the first historical data and the first starting historical data is determined to be the starting traffic state if the first historical data is not a null set; and the starting traffic state is determined according to a target traffic state in a second basic traffic map corresponding to the sensing blank region if the first historical data is a null set.

When the first sensing coverage region does not meet a state setting condition for the sensing upstream region, the service server fetches, from the first historical data, historical data corresponding to the simulation starting moment as the first starting historical data. The service server takes the first starting historical data as the starting traffic state corresponding to the sensing blank region. The starting traffic state includes starting vehicle density, starting vehicle flow, and a starting vehicle speed. According to the starting vehicle density, the service server may determine an average inter-vehicle distance D5 corresponding to the sensing blank region, i.e., a distance between two vehicles. Further, the service server generates a normal distribution N(D5, σ²) with the average inter-vehicle distance D5 as a mean. Specific distribution and variance are not limited in this embodiment of this application, as long as diversity is ensured. A process in which the service server fills the sensing upstream region with virtual simulated vehicles according to the normal distribution N(D5, σ²) is the same as the process in which the sensing upstream region is filled with virtual simulated vehicles according to the normal distribution N(D4, σ²), and therefore is not described herein. Please refer to the description above.

If the first sensing coverage region does not meet the state setting condition for the sensing upstream region and the first historical data is a null set, the service server randomly selects, according to a basic traffic map corresponding to the sensing upstream region, a vehicle density in a free traveling state (i.e., the target traffic state above) in the basic traffic map. According to the vehicle density, the service server may determine an average inter-vehicle distance D6, and the following process is the same as the process in which the service server fills the sensing upstream region with a virtual simulated vehicle (i.e., the first virtual simulated vehicle) according to the average inter-vehicle distance D4, and therefore is not described herein. Please refer to the description above.

For the sensing upstream region, the service server preferentially uses the traffic state of the sensing coverage region downstream thereof as an initial traffic state of the sensing upstream region at the simulation starting moment, because after the driving simulation system starts operating, at the sensing upper boundary 603a, traffic states on two sides can be as consistent as possible to prevent visual differences.

S206: Generate the first virtual simulated vehicle in the sensing blank region according to the starting traffic state.

Specifically, an average inter-vehicle distance corresponding to the sensing blank region is determined according to the starting traffic state; and the first virtual simulated vehicle is generated in the sensing blank region along a direction opposite to a traveling direction of the simulated main road according to the average inter-vehicle distance corresponding to the sensing blank region and a downstream edge of the sensing blank region if the regional position relationship is an upstream regional relationship or a midstream regional relationship. The upstream regional relationship is configured to represent that the sensing blank region is located in an upstream region of all the sensing coverage regions. The midstream regional relationship is configured to represent that a total quantity of the sensing coverage region is at least two and the sensing blank region is located between any two sensing coverage regions of the at least two sensing coverage regions.

For the sensing midstream region, as defined, sensing coverage regions exist upstream and downstream thereof. The processing in this case is the same as that of the sensing upstream region, and therefore is not described.

A processing process of S202 to S206 may be obtained with reference to FIG. 6B together. FIG. 6B is a schematic flowchart of a virtual simulated vehicle generation method for a sensing upstream/midstream region at a simulation starting moment according to an embodiment of this application. As shown in FIG. 6B, the method may include the following operations:

S2021: The service server determines whether the first sensing coverage region meets the state setting condition. S2022 is performed if the first sensing coverage region (or the first starting sensing data) meets the state setting condition. S2023 is performed if the first sensing coverage region does not meet the state setting condition.

S2022: The service server determines a starting traffic state according to a traffic state of the first sensing coverage region.

S2023: The service server determines whether first historical data exists in the sensing blank region. S2024 is performed if the first historical data exists, i.e., the first historical data is not a null set. S2025 is performed if the first historical data does not exist, i.e., the first historical data is a null set.

S2024: The service server determines the starting traffic state according to the first historical data.

S2025: The service server determines the starting traffic state according to a second basic traffic map.

S2026: The service server fills the upstream with a virtual simulated vehicle according to the starting traffic state.

In a feasible implementation, if the sensing midstream region between two sensing coverage regions is less than a certain length threshold, an initial state thereof may not be set, and it is considered that no vehicle exists therebetween. The threshold is not limited herein, which is related to a position and a type of the sensing device.

S207: In a simulation reproduction phase after the simulation starting moment, output, in the sensing coverage region, reproduced simulated driving behaviors of reproduced simulated vehicles corresponding to the sensing data, and output, in the sensing blank region according to an automatic driving model corresponding to the sensing blank region, virtual simulated driving behaviors of one or more second virtual simulated vehicles traveling in the sensing blank region; the one or more second virtual simulated vehicles including the first virtual simulated vehicle.

Specifically, the regional position relationship is an upstream regional relationship, the upstream regional relationship being configured to represent that the sensing blank region is located in an upstream region of all the sensing coverage regions; a first vehicle generation sub-region is determined in the sensing blank region according to an upstream edge of the sensing blank region and a vehicle generation line in the sensing blank region; the vehicle generation line is perpendicular to the traveling direction of the simulated main road; downstream sensing data corresponding to a second sensing coverage region is obtained from the sensing data; the second sensing coverage region being a region in the sensing coverage region and contiguous with the sensing blank region and downstream of the sensing blank region; a fourth virtual simulated vehicle is generated in the first vehicle generation sub-region according to the downstream sensing data, and the first virtual simulated vehicle and the fourth virtual simulated vehicle are determined to be the second virtual simulated vehicles; a first vehicle removal line perpendicular to the traveling direction of the simulated main road is determined in the sensing blank region; the first vehicle removal line being located in a downstream region of the first vehicle generation sub-region, and a distance between the first vehicle removal line and a downstream edge of the sensing blank region being less than a distance between a first starting vehicle and the downstream edge of the sensing blank region; the first starting vehicle being a virtual simulated vehicle in the first virtual simulated vehicle and closest to the downstream edge of the sensing blank region; and the virtual simulated driving behaviors of the one or more second virtual simulated vehicles are outputted in the sensing blank region according to the automatic driving model corresponding to the sensing blank region and the first vehicle removal line; the first vehicle removal line being configured to instruct the driving simulation system to remove, from the driving simulation system, a virtual simulated vehicle in the one or more second virtual simulated vehicles and traveling to the first vehicle removal line.

A specific process of generating a fourth virtual simulated vehicle in the first vehicle generation sub-region according to the downstream sensing data may include: generating the fourth virtual simulated vehicle in the first vehicle generation sub-region according to the downstream sensing data if the downstream sensing data meets the state setting condition for the sensing blank region; and obtaining third historical data of the sensing blank region and generating the fourth virtual simulated vehicle in the first vehicle generation sub-region according to the third historical data if the downstream sensing data does not meet the state setting condition.

Step S207 may further include: the second sensing coverage region including Z simulated lanes; Z being a positive integer; the Z simulated lanes including a simulated lane X_{y}, y being a positive integer and y being less than or equal to Z; obtaining, from the downstream sensing data, a quantity of a reproduced simulated vehicle U_{y} in the simulated lane X_{y}; the reproduced simulated vehicle U_{y} being one of the reproduced simulated vehicles corresponding to the reproduced simulated driving behaviors; determining that the downstream sensing data meets the state setting condition if a total quantity of the reproduced simulated vehicle U_{y} is at least two; and determining that the simulated lane X_{y} belongs to a simulated blank lane if the total quantity of the reproduced simulated vehicle U_{y} is less than or equal to 1, and determining that the downstream sensing data does not meet the state setting condition if the Z simulated lanes belong to the simulated blank lane.

A specific process of generating the fourth virtual simulated vehicle in the first vehicle generation sub-region according to the downstream sensing data if the downstream sensing data meets the state setting condition for the sensing blank region may include: determining reproduction timestamps respectively corresponding to the at least two reproduced simulated vehicles U_{y}, determining an average reproduction time interval corresponding to the simulated lane X_{y} according to the at least two reproduction timestamps, and determining an average reproduction time interval corresponding to the first vehicle generation sub-region according to an average reproduction time interval corresponding to the Z simulated lanes; determining vehicle speeds respectively corresponding to the at least two reproduced simulated vehicles U_{y}, determining an average vehicle speed corresponding to the simulated lane X_{y} according to the at least two reproduction vehicle speeds, and determining an average vehicle speed corresponding to the first vehicle generation sub-region according to an average vehicle speed corresponding to the Z simulated lanes; and generating the fourth virtual simulated vehicle, whose initial speed is the average vehicle speed corresponding to the first vehicle generation sub-region, in the first vehicle generation sub-region according to the average reproduction time interval corresponding to the first vehicle generation sub-region.

A specific process of generating the fourth virtual simulated vehicle in the first vehicle generation sub-region according to the third historical data may include: obtaining reproduced historical data from the third historical data and generating the fourth virtual simulated vehicle in the first vehicle generation sub-region according to the reproduced historical data if the third historical data is not a null set; and generating the fourth virtual simulated vehicle in the first vehicle generation sub-region according to a target traffic state in a fourth basic traffic map corresponding to the sensing blank region if the third historical data is a null set.

Step S207 may further include: obtaining an initial automatic driving model corresponding to the sensing blank region, and obtaining third historical data of the sensing blank region; adjusting, if the third historical data is not a null set, parameters in the initial automatic driving model corresponding to the sensing blank region according to the third historical data to obtain the automatic driving model corresponding to the sensing blank region; and adjusting, if the third historical data is a null set, parameters in the initial automatic driving model corresponding to the sensing blank region according to a road type corresponding to the sensing blank region to obtain the automatic driving model corresponding to the sensing blank region.

Step S207 may further include: determining a virtual simulated vehicle in the one or more second virtual simulated vehicles and closest to the downstream edge of the sensing blank region to be a downstream vehicle (i.e., a first vehicle) in the sensing blank region; determining a maximum vehicle speed of the downstream vehicle according to downstream sensing data; determining a virtual simulated vehicle in the one or more second virtual simulated vehicles except the downstream vehicle to be a first upstream vehicle; and determining a maximum vehicle speed of the first upstream vehicle according to a road type corresponding to the sensing blank region. Then, a specific process of outputting the virtual simulated driving behaviors of the one or more second virtual simulated vehicles in the sensing blank region according to the automatic driving model corresponding to the sensing blank region and the first vehicle removal line may include: outputting the virtual simulated driving behaviors of the one or more second virtual simulated vehicles in the sensing blank region according to the automatic driving model corresponding to the sensing blank region, the first vehicle removal line, the maximum vehicle speed of the first upstream vehicle, and the maximum vehicle speed of the downstream vehicle.

A specific process of determining a maximum vehicle speed of the downstream vehicle according to downstream sensing data may include: determining, if the downstream sensing data indicates that reproduced simulated vehicles exist in the second sensing coverage region, a reproduced simulated vehicle in the reproduced simulated vehicles in the second sensing coverage region that is closest to an upstream edge of the second sensing coverage region to be a second upstream vehicle; determining a vehicle speed of the second upstream vehicle to be the maximum vehicle speed of the downstream vehicle; a simulated lane to which the second upstream vehicle belongs being the same as a simulated lane to which the downstream vehicle belongs; obtaining a historical vehicle speed from the third historical data and determining the historical vehicle speed to be the maximum vehicle speed of the downstream vehicle if the downstream sensing data indicates that no reproduced simulated vehicle exists in the second sensing coverage region and the third historical data of the sensing blank region is not a null set; and determining the maximum vehicle speed of the downstream vehicle according to a road type corresponding to the sensing blank region if the downstream sensing data indicates that no reproduced simulated vehicle exists in the second sensing coverage region and the third historical data of the sensing blank region is a null set.

For the sensing upstream region, as the name suggests, a sensing coverage region exists downstream thereof. Referring to FIG. 6C together, FIG. 6C is a schematic diagram showing a scenario of outputting a virtual simulated driving behavior in a sensing upstream region according to an embodiment of this application. As shown in FIG. 6C, the simulated main road includes a sensing coverage region 601c and a sensing blank region 602c. In this case, the sensing blank region 602c may be referred to as a sensing upstream region, and the sensing coverage region 601c may be referred to as a second sensing coverage region of the sensing upstream region. A reproduced simulated vehicle in the sensing coverage region 601c and a reproduced simulated driving behavior outputted are both determined by the sensing data.

At the simulation starting moment, an initial vehicle for filling, for example, the first virtual simulated vehicle as described in S206 above, exists in the sensing upstream region. After the driving simulation system starts operating, the virtual simulated vehicle in the sensing upstream region may simulate longitudinal and transverse driving behaviors of the virtual simulated vehicle in the region through an automatic driving model (including a following model and a lane changing model) corresponding to the sensing upstream region. To be distinguished from automatic driving models corresponding to other sensing blank regions, the automatic driving model corresponding to the sensing upstream region is defined as an upstream automatic driving model in this embodiment of this application.

Referring to FIG. 6C again, after the simulation starts operating, a simulated vehicle in the second sensing coverage region (i.e., the sensing coverage region 601c) is reproduced from the sensing data. Therefore, a virtual simulated vehicle in the sensing upstream region (i.e., the sensing blank region 602c) cannot be introduced into the sensing coverage region. Otherwise, a potential collision or conflict of vehicles may occur. Based on this, an embodiment of this application provides a vehicle generation line 605c and a vehicle removal line 604c (i.e., the first vehicle removal line). The vehicle generation line 605c is at a distance of D7 from an upstream edge of the sensing upstream region, i.e., a distance between the upstream edge of the sensing upstream region and the vehicle generation line 605c is D7. The vehicle generation line 605c is a line segment perpendicular to the lane direction (under the ST coordinate system). The vehicle removal line 604c is a line segment downstream of the sensing upstream region, at a distance of D8 from an upstream edge of the sensing coverage region 601c, and perpendicular to the lane direction. To be specific, a distance between a downstream edge of the sensing upstream region and the vehicle removal line 604c is D8.

A road portion between the vehicle generation line 605c and the upstream edge of the sensing upstream region forms the first vehicle generation sub-region. After the simulation starts operating, the service server randomly generates a virtual simulated vehicle on a lane center line of the first vehicle generation sub-region. Herein, an initial position of the virtual simulated vehicle in a departure zone (i.e., the first vehicle generation sub-region) is not limited, as long as randomness is maintained, which can prevent appearance of the virtual simulated vehicle in the driving simulation system from a same place.

A processing process of this operation may be obtained with reference to FIG. 6D together. FIG. 6D is a schematic flowchart of a virtual simulated vehicle generation method for a sensing upstream region in a simulation reproduction phase according to an embodiment of this application. As shown in FIG. 6D, the method includes the following operations.

S2031: The service server determines whether a simulated vehicle exists in the second sensing coverage region. Specifically, if a simulated vehicle exists in the second sensing coverage region, S2032 is performed, and if no simulated vehicle exists in the second sensing coverage region, S2033 is performed.

S2032: The service server determines a traffic state according to a traffic state of the second sensing coverage region; preferentially adjusts parameters of an initial automatic driving model according to third historical data; and determines a maximum vehicle speed of a first vehicle according to a speed of a last vehicle. Specifically, if the second sensing coverage region meets the state setting condition, a traffic flow initial speed entering the driving simulation system and a departure time interval between two vehicles may be assigned values based on sensed realistic vehicles. For example, an initial vehicle speed is the same as an average speed of the sensed vehicles, and a departure interval is the same as an average time interval of the sensed vehicles. If historical data (the historical data herein is referred to as third historical data) exists in the sensing upstream region, the service server calibrate parameters of an initial upstream automatic driving model in advance through the third historical data, so that the model behaves similarly to the historical data of the sensing upstream region. The first vehicle in FIG. 6D is the downstream vehicle above, for example, the first vehicle 601d, the first vehicle 602d, and the first vehicle 603d illustrated in FIG. 6C. The last vehicle in FIG. 6D is the first upstream vehicle above, for example, the last vehicle 601e, the last vehicle 602e, and the last vehicle 603e illustrated in FIG. 6C.

S2033: The service server determines whether the third historical data exists in the sensing upstream region. Specifically, S2034 is performed if the third historical data exists; and S2035 is performed if the third historical data does not exist.

S2034: The service server determines the traffic state according to the third historical data; adjusts the parameters of the initial automatic driving model according to the third historical data; and determines the maximum vehicle speed of the first vehicle according to the third historical data. Specifically, the service server assigns values to the traffic flow initial speed and the departure time interval between two vehicles according to the third historical data.

S2035: The service server determines the traffic state according to a fourth basic traffic map; adjusts the parameters of the initial automatic driving model according to a road type; and determines the maximum vehicle speed of the first vehicle according to the road type. If the second sensing coverage region does meet the state setting condition and the third historical data does not exist in the sensing upstream region, a traffic state in a free driving state (i.e., the target traffic state) is randomly selected from a basic traffic map corresponding to the sensing upstream region (referred to as the fourth basic traffic map), and values are assigned to the initial speed and the departure interval. If the third historical data does not exist, the service server may use default model parameters through the road type.

S2036: The service server generates a fourth virtual simulated vehicle in the first vehicle generation sub-region according to the traffic state; and determines a maximum vehicle speed of the remaining vehicles except the first vehicle according to the road type. S2037: The service server removes a vehicle traveling to the first vehicle removal line. Specifically, since reproduced simulation of the sensed realistic vehicles exist downstream of the sensing upstream region, i.e., in the sensing coverage region, the virtual simulated vehicle in the sensing upstream region cannot enter the sensing coverage region. Therefore, any virtual simulated vehicle (including vehicles for filling existing at an initial moment and virtual vehicles generated in the departure zone after the simulation starts operating) is removed from the driving simulation system when reaching the first vehicle removal line, to prevent a conflict with a reproduced vehicle in the sensing coverage region. D7 and D8 in FIG. 6C are not limited in this embodiment of this application, as long as D7 ensures that initial positions of vehicles appearing in the departure zone (i.e., the first vehicle generation sub-region) have spatial diversity, i.e., the vehicles do not depart from a same place; and D8 ensures that a vehicle in the sensing upstream region is removed from the system before entering the sensing coverage region, without causing any conflict. A confirmation that a vehicle hits a closing line or a map edge is removed from the system may be set as that a front edge of the vehicle or a center of mass crosses the line, which is not limited herein.

S208: In a simulation prediction phase after the simulation reproduction phase, output, on the simulated main road according to an automatic driving model corresponding to the simulated main road, a predicted simulated driving behavior of a third virtual simulated vehicle traveling on the simulated main road to obtain a predicted traffic state of the simulated main road, the predicted traffic state of the simulated main road being configured to control a traveling state of a physical vehicle traveling on a physical road corresponding to the simulated main road.

Specifically, after the simulation prediction phase is entered, injection of the sensing data into the driving simulation system is stopped, and driving behaviors of all vehicles in the driving simulation system are controlled by a microscopic traffic model. To be specific, for the simulated vehicle in each sensing region, longitudinal and transverse driving behaviors of the simulated vehicle are controlled by an automatic driving model corresponding to each sensing region.

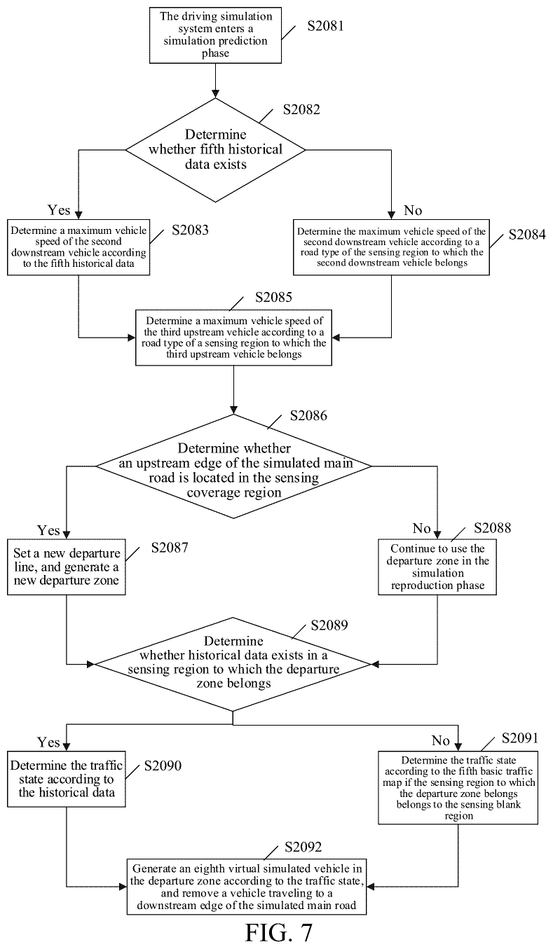

Referring to FIG. 7 together, FIG. 7 is a schematic flowchart of a predicted driving simulation behavior generation method according to an embodiment of this application. As shown in FIG. 7, the method may include S2081 to S2092. An execution sequence of S2082 to S2085 and an execution sequence of S2086 to S2092 are not limited in this embodiment of this application, which may be set according to an actual application scenario.

S2081: The driving simulation system enters a simulation prediction phase.

S2082: The service server determines whether fifth historical data exists. The fifth historical data refers to historical data corresponding to a sensing region to which a most downstream simulated vehicle (i.e., the second downstream vehicle) on the simulated main road belongs. S2083 is performed if the fifth historical data exists (i.e., the fifth historical data is not a null set). S2084 is performed if the fifth historical data does not exist (i.e., the fifth historical data is a null set).

S2083: The service server determines a maximum vehicle speed of the second downstream vehicle according to the fifth historical data.

S2084: Determine the maximum vehicle speed of the second downstream vehicle according to a road type of the sensing region to which the second downstream vehicle belongs.

S2085: The service server determines a maximum vehicle speed of the third upstream vehicle according to a road type of a sensing region to which the third upstream vehicle belongs.

S2086: Determine whether an upstream edge of the simulated main road is located in the sensing coverage region. If the upstream edge is located in the sensing coverage region, S2087 is performed. If not located in the sensing coverage region, the upstream edge is located in the sensing upstream region in the sensing blank region. In this case, S2088 is performed.

S2087: Set a new departure line, and generate a new departure zone. To be specific, the service server generates a new departure line (i.e., a vehicle generation line) in the most upstream sensing coverage region.

S2088: Continue to use the departure zone in the simulation reproduction phase, for example, the departure zone illustrated in FIG. 6C.

S2089: Determine whether historical data exists in a sensing region to which the departure zone belongs. The departure zone in FIG. 7 is the second vehicle generation sub-region above. S2090 is performed if the corresponding historical data exists. S2091 is performed if the corresponding historical data does not exist.

S2090: Determine the traffic state according to the historical data. The historical data in FIG. 7 is the fourth historical data described above.

S2091: Determine the traffic state according to the fifth basic traffic map if the sensing region to which the departure zone belongs to the sensing blank region.

S2092: Generate an eighth virtual simulated vehicle in the departure zone according to the traffic state, and remove a vehicle traveling to a downstream edge of the simulated main road.

As can be seen from the above, in this embodiment of this application, at the simulation starting moment and in the simulation reproduction phase, the sensing blank region without sensing data is described in terms of simulated vehicles, so accuracy of reproduction of the driving simulation system for the simulated main road can be improved. In addition, in this embodiment of this application, simulation of the simulated main road in different simulation phases is described respectively, so accuracy of prediction of the driving simulation system for the simulated main road can be improved.

Referring to FIG. 8, FIG. 8 is a schematic flowchart of a data processing method according to an embodiment of this application. The method may be performed by a service server (e.g., the service server 100 shown in FIG. 1 above), or performed by a terminal device (e.g., the terminal device 200a shown in FIG. 1 above), or interactively performed by the service server and the terminal device. For ease of understanding, this embodiment of this application is described with an example in which the method is performed by the terminal device. As shown in FIG. 8, the method may include at least the following operations.

S301: Determine, in a driving simulation system, a sensing coverage region with sensing data and a sensing blank region not overlapping with the sensing coverage region in a simulated main road, the sensing blank region having no sensing data.

S302: Generate, at a simulation starting moment, a first virtual simulated vehicle in the sensing blank region according to a regional position relationship between the sensing coverage region and the sensing blank region.

A specific implementation process of S301 to S302 may be obtained with reference to S101 to S102 in the embodiment corresponding to FIG. 2, which is not described herein.

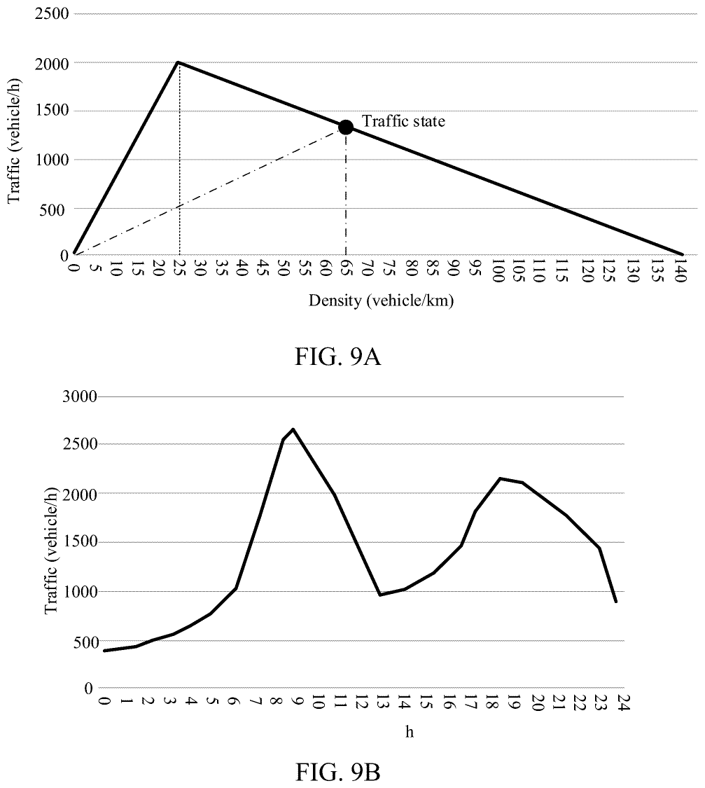

In traffic flow theory, a basic traffic map may describe a relationship among macroscopic vehicle flow, vehicle density, and vehicle speeds in a traffic network. Referring to FIG. 9A together, FIG. 9A is a schematic diagram showing a basic traffic map according to an embodiment of this application. A horizontal axis of the basic traffic map represents vehicle density, and a vertical axis represents vehicle flow. The basic traffic map may be approximated as two straight line segments, forming a triangle with the horizontal axis. Each point on the straight line segment represents a traffic state. The first straight line segment describes a free traveling state of a vehicle, which is called a target traffic state in this embodiment of this application, and a slope thereof is a free-flow vehicle speed Vₘₐₓ. In FIG. 9A, taking 80 km/h as an example, when the vehicle density increases from 0 to critical density K_{cr} (e.g., 25 vehicles/km in FIG. 9A), the free-flow vehicle speed remains unchanged, a traffic capacity (i.e., flow) gradually increases, and a maximum traffic capacity Qₘₐₓ (e.g., 2000 vehicles/h in FIG. 9A) is reached at the critical density K_{cr}. When the density continues to increase due to a continued increase in vehicles, the vehicle speed gradually decreases, a congestion state is entered, and the traffic capacity decreases accordingly, as shown by the second straight line segment. When the vehicle density increases to congestion density Kⱼₐₘ (e.g., 140 vehicles/km in FIG. 9A), the traffic flow enters a complete congestion stop state, and the vehicle speed and the traffic capacity both decrease to 0.

The congestion density Kⱼₐₘ in the basic traffic map only depends on a distance from front to front when the traffic flow is in a complete congestion state. The maximum traffic capacity Qₘₐₓ and the free-flow vehicle speed are road-type related parameters, which may be obtained by parameter correction or querying relevant specifications. The two straight line segments in the basic traffic map can be uniquely determined from the three parameters. Herein, the manner of obtaining the basic traffic map is not limited, which may be defined by giving the above parameters in a scenario file, or different default basic traffic maps may be set within the simulation system to define basic traffic attributes of different types of roads.

When the vehicle density is given, the service server may uniquely determine a traffic state of a vehicle according to the basic traffic map, thereby determining a traffic speed. A distance D between vehicle centers of mass and the traffic density K are in a reciprocal relationship. Therefore, when the traffic density K is given, the service server may calculate an initial inter-vehicle distance D and a speed V of the vehicle.

In this embodiment of this application, basic traffic maps corresponding to different sensing regions are independent. For example, the basic traffic map corresponding to the second sensing coverage region and the basic traffic map corresponding to the third sensing coverage region are independent of each other. Therefore, the basic traffic map corresponding to the second sensing coverage region may be the same as the basic traffic map corresponding to the third sensing coverage region, and the basic traffic map corresponding to the second sensing coverage region may be different from the basic traffic map corresponding to the third sensing coverage region. The basic traffic map corresponding to the sensing upstream region and the basic traffic map corresponding to the sensing downstream region are independent of each other. Therefore, the basic traffic map corresponding to the sensing upstream region may be the same as the basic traffic map corresponding to the sensing downstream region; and the basic traffic map corresponding to the sensing upstream region may be different from the basic traffic map corresponding to the sensing downstream region.

Before the simulation operates, an administrator may be allowed to set default parameters such as the free-flow speed Vₘₐₓ, the congestion density Kⱼₐₘ, the critical density K_{cr}, and the maximum traffic capacity Qₘₐₓ, or adopt default values, to generate a basic traffic map. The basic traffic map may also be referred to as a macro basic map.

When there is a need to generate a virtual simulated vehicle, the service server may calculate the traffic density K according to a reciprocal of the inter-vehicle distance D. Therefore, a traffic status (such as flow, speed, and density) can be uniquely determined from the basic traffic map, thereby obtaining an initial speed and an inter-vehicle time interval of the virtual simulated vehicle. A relationship between the inter-vehicle distance D and the traffic density K (i.e., vehicle density) may be obtained with reference to the following formula (1), and the initial speed V of the vehicle may be determined through the following formula (2).

$$D = 1 / K \qquad ( 1 )$$

$$\begin{matrix}V = {V}_{max} & ( K \leq {K}_{c r} ) \\ V = ( K {Q}_{max} / ( {K}_{c r} - {K}_{j a m} ) + {k}_{j a m} {Q}_{max} / ( {K}_{j a m} - {K}_{c r} ) ) / K & ( K > {K}_{c r} )\end{matrix} \qquad ( 2 )$$

On an actual road, for example, a highway, a sensing device coverage rate may not be high. To be specific, real-time vehicle trajectory data cannot cover all highway sections that need to be simulated. In a section not covered by any sensing device, there is a need to first determine whether a historical traffic state described by historical data exists. The historical data may include aggregated data such as average vehicle flow/average vehicle density/an average vehicle speed collected by a bayonet device. Referring to FIG. 9B together, FIG. 9B is a polyline example diagram showing average vehicle flow according to an embodiment of this application. FIG. 9B shows a polyline diagram showing a line chart of 24-hour average traffic with time granularity that may range from a minute level, e.g., 5 minutes, 10 minutes, 15 minutes, and 30 minutes, to an hour level. According to classification of data sources, similar data curves for vehicle density and average speeds may also be available. After the simulation operates, the service server may make certain settings for current simulation by means of historical data.

In this embodiment of this application, historical data corresponding to different sensing regions are independent. For example, the historical data corresponding to the second sensing coverage region and the historical data corresponding to the third sensing coverage region are independent of each other. Therefore, the historical data corresponding to the second sensing coverage region may be the same as the historical data corresponding to the third sensing coverage region; and the historical data corresponding to the second sensing coverage region may be different from the historical data corresponding to the third sensing coverage region. In some application scenarios, the historical data corresponding to the second sensing coverage region may exist, but the historical data corresponding to the third sensing coverage region does not exist.

If a section of the sensing blank region is too long, the section may be divided into several smaller sections with equal lengths. In this case, the historical data is considered separately for the smaller sections.

If the historical data is a time-varying curve that changes over time (as shown in FIG. 9B), the assignment may alternatively be set separately according to simulation time. For example, during deduction, if historical data exists for average vehicle flow, average vehicle density, and an average vehicle speed every 15 minutes, the simulation time may be set accordingly. To be specific, parameters that need to be set may be adjusted accordingly every 15 minutes to be as consistent as possible with the historical data.

S303: In a simulation reproduction phase after the simulation starting moment, output reproduced simulated driving behaviors of reproduced simulated vehicles corresponding to the sensing data in the sensing coverage region, and determine, if the regional position relationship is a midstream regional relationship, a reproduced simulated vehicle in reproduced simulated vehicles in the third sensing coverage region that travels to the sensing blank region to be a fifth virtual simulated vehicle; the midstream regional relationship being configured to represent that a total quantity of the sensing coverage region is at least two and the sensing blank region is located between any two sensing coverage regions of the at least two sensing coverage regions; the reproduced simulated vehicles in the third sensing coverage region being generated through the sensing data; and the third sensing coverage region being a region in the at least two sensing coverage regions that is contiguous with the sensing blank region and downstream of the sensing blank region.

S304: Determine the first virtual simulated vehicle and the fifth virtual simulated vehicle to be the second virtual simulated vehicles.

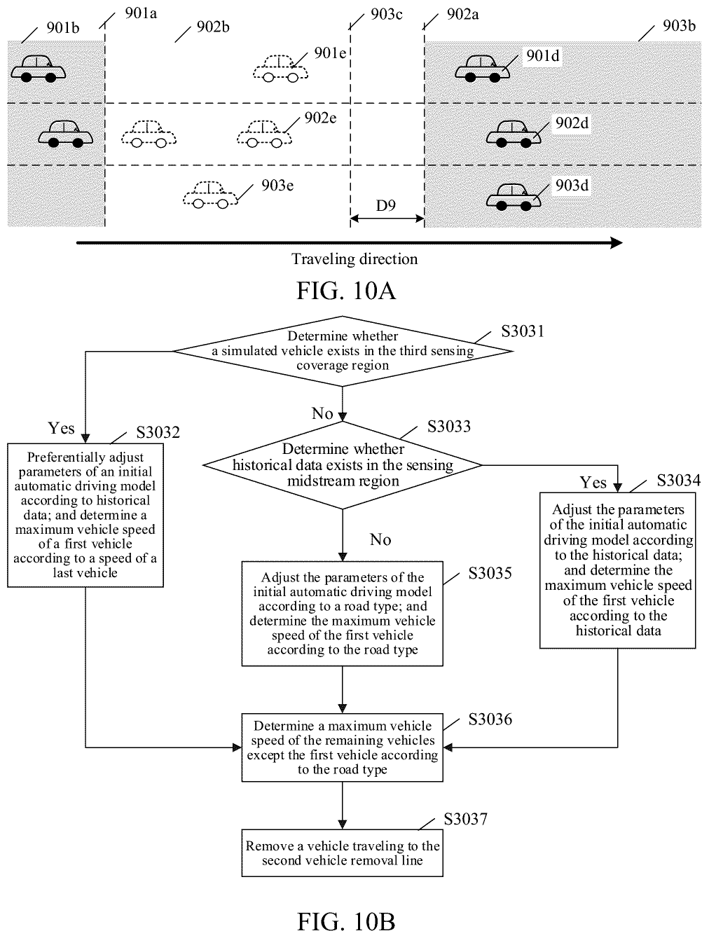

Specifically, refer to the description in S303 and S304. For the sensing midstream region, as the name suggests, sensing coverage regions exist upstream and downstream thereof. Referring to FIG. 10A together, FIG. 10A is a schematic diagram showing a scenario of outputting a virtual driving simulation behavior in a sensing midstream region according to an embodiment of this application. As shown in FIG. 10A, the simulated main road includes a sensing coverage region 901b, a sensing blank region 902b, and a sensing coverage region 903b. In this case, the sensing blank region 902b may be referred to as a sensing midstream region, and the sensing coverage region 903b may be referred to as a third sensing coverage region of the sensing midstream region. A reproduced simulated vehicle in the sensing coverage region 901b and a reproduced simulated driving behavior outputted are both determined by sensing data corresponding to the sensing coverage region 901b. A reproduced simulated vehicle in the sensing coverage region 903b and a reproduced simulated driving behavior outputted are both determined by sensing data corresponding to the sensing coverage region 903b.

After the simulation starts operating, a vehicle traveling from the third sensing coverage region (the sensing coverage region 901b as shown in FIG. 10A), i.e., a simulated vehicle traveling from the third sensing coverage region, is received upstream of the sensing midstream region. After the simulated vehicle crosses a sensing lower boundary 901a and enters the sensing midstream region, longitudinal and transverse driving behaviors of the simulated vehicle and a vehicle with which the sensing midstream region is filled are simulated by an automatic driving model corresponding to the sensing midstream region. To be distinguished from automatic driving models corresponding to other sensing blank regions, the automatic driving model corresponding to the sensing midstream region is defined as a midstream automatic driving model in this embodiment of this application. The midstream automatic driving model is not limited herein. If historical data exists in the sensing midstream region, the service server calibrate parameters of an initial midstream automatic driving model in advance through the historical data, so that the midstream automatic driving model behaves similarly to the historical data of the sensing midstream region. If the historical data does not exist, the service server may use default model parameters through a road type corresponding to the sensing midstream region.

A first vehicle in the sensing midstream region refers to a simulated vehicle closest to a downstream edge of the sensing midstream region. Referring to FIG. 10A again, the first vehicle in the sensing midstream region may include a simulated vehicle 901e, a simulated vehicle 902c, and a simulated vehicle 903c. The service server determines a speed of a last vehicle in a corresponding same lane to be a maximum vehicle speed of the first vehicle. The last vehicle for the sensing midstream region may include 901d in a same lane as the simulated vehicle 901c, 902d in a same lane as the simulated vehicle 902e, and 903d in a same lane as the simulated vehicle 903c. The last vehicle corresponding to the sensing midstream region refers to a simulated vehicle in the third sensing coverage region and closest to an upstream edge (i.e., a sensing upper boundary 902a). It is clear that the speed of the first vehicle in the sensing midstream region may not exceed the speed of the last vehicle in the third sensing coverage region. Therefore, continuity of traffic states can be ensured.

When the first vehicle in the sensing midstream region travels to a closing line 903c (i.e., a second vehicle removal line), the first vehicle may be removed from the driving simulation system, while an upstream vehicle in a same lane thereof may become a new first vehicle in the lane. If no vehicle exists in the third sensing coverage region, the service server preferentially confirms whether historical data exists in the sensing midstream region. If the historical data exists, an average speed in the historical data is assigned to the first vehicle in each lane in the sensing midstream region. If no vehicle exists in the third sensing coverage region and no historical data exists in the sensing midstream region, the service server may set a maximum vehicle speed of the first vehicle in the sensing midstream region through a road type or a road speed limit corresponding to the sensing midstream region. In addition, a maximum speed of the remaining vehicles in the sensing midstream region except the first vehicle may be set through a road type or a road speed limit corresponding to the sensing blank region.

S305: Determine, in the sensing blank region, a second vehicle removal line perpendicular to the traveling direction of the simulated main road; a distance between the second vehicle removal line and a downstream edge of the sensing blank region being less than a distance between a second starting vehicle and the downstream edge of the sensing blank region; and the second starting vehicle being a virtual simulated vehicle in the first virtual simulated vehicle and closest to the downstream edge of the sensing blank region.

Specifically, to ensure that there is no conflict with the vehicle in the third sensing coverage region, the closing line 903c, i.e., the second vehicle removal line, is set downstream of the sensing midstream region, so that the simulated vehicle in the sensing midstream region is removed from the driving simulation system after hitting the closing line 903c, preventing a collision or conflict with the reproduced vehicle in the third sensing coverage region. Herein, a width of D9 is not limited, as long as D9 ensures that a vehicle in the sensing midstream region is removed from the system before entering the sensing coverage region 903b, without causing any conflict.

S306: Output the virtual simulated driving behaviors of the one or more second virtual simulated vehicles in the sensing blank region according to the automatic driving model corresponding to the sensing blank region and the second vehicle removal line; the second vehicle removal line being configured to instruct the driving simulation system to remove, from the driving simulation system, a virtual simulated vehicle in the one or more second virtual simulated vehicles and traveling to the second vehicle removal line.

A processing process of S303 to S306 may be obtained with reference to FIG. 10B together. FIG. 10B is a schematic flowchart of a virtual simulated vehicle generation method for a sensing midstream region in a simulation reproduction phase according to an embodiment of this application. As shown in FIG. 10B, the method includes the following operations.

S3031: The service server determines whether a simulated vehicle exists in the third sensing coverage region. Specifically, if a simulated vehicle exists in the third sensing coverage region, S3032 is performed, and if no simulated vehicle exists in the third sensing coverage region, S3033 is performed.

S3032: The service server preferentially adjusts parameters of an initial automatic driving model according to historical data (which refers to historical data corresponding to the sensing midstream region herein); and determines a maximum vehicle speed of a first vehicle according to a speed of a last vehicle. Specifically, the service server preferentially calibrates parameters of an initial midstream automatic driving model according to the historical data corresponding to the sensing midstream region, so that the model behaves similarly to the historical data of the sensing midstream region. The first vehicle in FIG. 10B is the first vehicle 901e, the first vehicle 902e, and the first vehicle 903e as illustrated in FIG. 10A. The last vehicle in FIG. 10B is the last vehicle 901d, the last vehicle 902d, and the last vehicle 903d as illustrated in FIG. 10A.

S3033: The service server determines whether historical data exists in the sensing midstream region. Specifically, S3034 is performed if the historical data exists; and S3035 is performed if the historical data does not exist.

S3034: The service server adjusts the parameters of the initial automatic driving model according to the historical data; and determines the maximum vehicle speed of the first vehicle according to the historical data.

S3035: The service server adjusts the parameters of the initial automatic driving model according to a road type corresponding to the sensing midstream region; and determines the maximum vehicle speed of the first vehicle according to the road type.

S3036: The service server determines a maximum vehicle speed of the remaining vehicles except the first vehicle according to the road type.

S3037: The service server removes a vehicle traveling to the second vehicle removal line.

S307: In a simulation reproduction phase after the simulation starting moment, output, in the sensing coverage region, reproduced simulated driving behaviors of reproduced simulated vehicles corresponding to the sensing data, and output, in the sensing blank region, virtual simulated driving behaviors of one or more second virtual simulated vehicles according to an automatic driving model corresponding to the sensing blank region; the one or more second virtual simulated vehicles including the first virtual simulated vehicle.

S308: In a simulation prediction phase after the simulation reproduction phase, output, on the simulated main road according to an automatic driving model corresponding to the simulated main road, a predicted simulated driving behavior of a third virtual simulated vehicle to obtain a predicted traffic state of the simulated main road, the predicted traffic state of the simulated main road being configured to control a traveling state of a physical vehicle traveling on a physical road corresponding to the simulated main road.

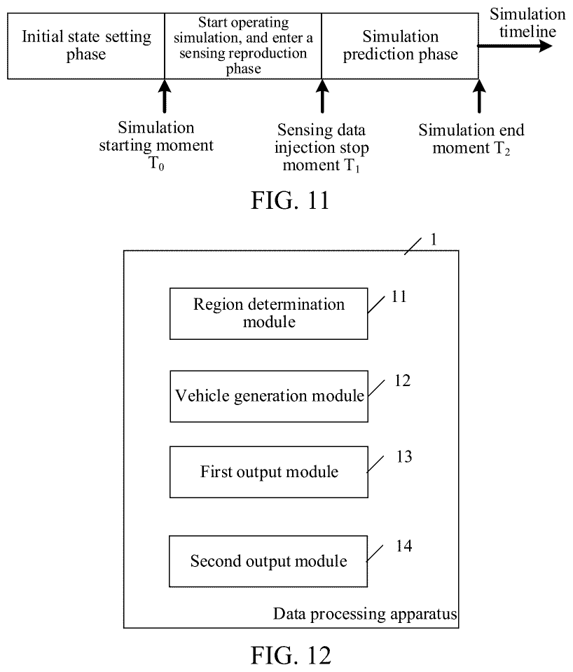

In a microscopic traffic simulation system, each time the simulation clock is advanced, a speed and a position of the simulated vehicle in the system may be updated. A movement behavior thereof may be described by following and lane changing microscopic driving behavior models. In the digital twin simulation system, according to timeline, the simulation may be divided into the following phases. Referring to FIG. 11, FIG. 11 is an example diagram showing simulation deduction of a simulated main road for “time” according to an embodiment of this application. As shown in FIG. 11, in an initial state setting phase, in FIG. 11, the simulation starting moment is represented with T₀, and at this moment, there is a need to set an initial state when the simulation starts operating, including a realistic vehicle sensed in the sensing coverage region at the simulation starting moment and an initial simulated vehicle in the sensing blank region, i.e., a first virtual simulated vehicle. When the initial state at the moment T₀ is set and the upstream/downstream is filled with vehicles, a maximum number of vehicles with which each region may be filled may be limited to such an extent that a range of a map is not exceeded. When each region is filled with vehicles according to the foregoing rule, the filling may be stopped when the maximum number is reached. An inter-vehicle distance D during filling and an inter-vehicle time interval generated in the departure zone may be determined by random numbers that conform to a distribution, and random seeds may be defined separately, to ensure consistency of the random numbers during multiple simulations.

In a sensing reproduction phase, after digital twin simulation starts operating, the sensing device transmits vehicle information (states such as positions, speeds, and attitudes) in the sensing coverage region back to the driving simulation system in real time, and reproduces the vehicle information in the driving simulation system, and the virtual simulated vehicle in the sensing blank region (including the sensing upstream region, the sensing midstream region, and the sensing downstream region) is also simulated through the corresponding automatic driving model.

In a simulation prediction phase, the digital twin simulation system may perform deduction simulation to predict a traffic situation in a future period of time. In FIG. 11, a deduction start moment is represented with T₁. From this moment, injection of sensing data into the driving simulation system is stopped, and the driving simulation system enters a simulation deduction phase, operates the simulation through a traffic state at the moment T₁, and predicts a traffic state in a future period of time from the simulation. If a simulation end moment is represented with T₂, simulation prediction and deduction are performed between T₁ and T₂. There is no real-time injection of sensing data in this phase. All vehicles in the system are simulated according to preset models.

The embodiments involved in this application, for example, the embodiments corresponding to FIG. 2, FIG. 5, and FIG. 8 respectively, may be combined to generate new embodiments.

As can be seen from the above, in this embodiment of this application, at the simulation starting moment and in the simulation reproduction phase, the sensing blank region without sensing data is described in terms of simulated vehicles, so accuracy of reproduction of the driving simulation system for the simulated main road can be improved. In addition, in this embodiment of this application, simulation of the simulated main road in different simulation phases is described respectively, so accuracy of prediction of the driving simulation system for the simulated main road can be improved.

Further, referring to FIG. 12, FIG. 12 is a schematic structural diagram of a data processing apparatus according to an embodiment of this application. The above data processing apparatus 1 may be configured to perform the corresponding steps in the method provided in the embodiments of this application. As shown in FIG. 12, the data processing apparatus 1 may include: a region determination module 11, a vehicle generation module 12, a first output module 13, and a second output module 14.

The region determination module 11 is configured to determine, in a driving simulation system, a sensing coverage region with sensing data and a sensing blank region not overlapping with the sensing coverage region in a simulated main road. The sensing blank region has no sensing data.

The vehicle generation module 12 is configured to generate, at a simulation starting moment, a first virtual simulated vehicle in the sensing blank region according to a regional position relationship between the sensing coverage region and the sensing blank region.

The first output module 13 is configured to, in a simulation reproduction phase after the simulation starting moment, output, in the sensing coverage region, reproduced simulated driving behaviors of reproduced simulated vehicles corresponding to the sensing data, and output, in the sensing blank region according to an automatic driving model corresponding to the sensing blank region, virtual simulated driving behaviors of one or more second virtual simulated vehicles traveling in the sensing blank region. The one or more second virtual simulated vehicles include the first virtual simulated vehicle.

The second output module 14 is configured to, in a simulation prediction phase after the simulation reproduction phase, output, on the simulated main road according to an automatic driving model corresponding to the simulated main road, a predicted simulated driving behavior of a third virtual simulated vehicle traveling on the simulated main road to obtain a predicted traffic state of the simulated main road, the predicted traffic state of the simulated main road being configured to control a traveling state of a physical vehicle traveling on a physical road corresponding to the simulated main road.

As can be seen from the above, in this embodiment of this application, at the simulation starting moment and in the simulation reproduction phase, the sensing blank region without sensing data is described in terms of simulated vehicles, so accuracy of reproduction of the driving simulation system for the simulated main road can be improved. In addition, in this embodiment of this application, simulation of the simulated main road in different simulation phases is described respectively, so accuracy of prediction of the driving simulation system for the simulated main road can be improved.

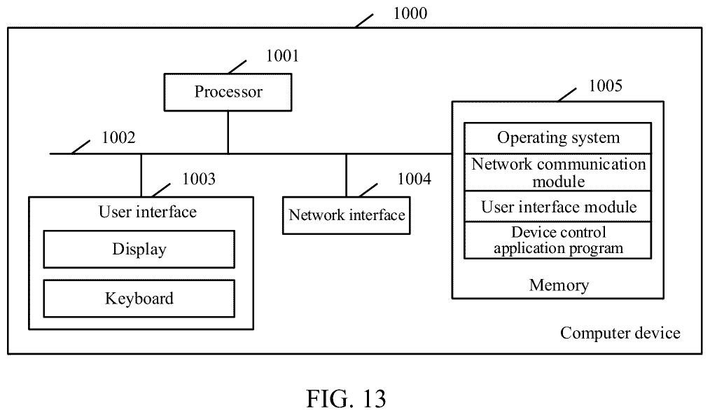

Further, referring to FIG. 13, FIG. 13 is a schematic structural diagram of a computer device according to an embodiment of this application. As shown in FIG. 13, the computer device 1000 may include: at least one processor 1001, for example, a CPU, at least one network interface 1004, a user interface 1003, a memory 1005, and at least one communication bus 1002. The communication bus 1002 is configured to implement connection and communication between these components. In some embodiments, the user interface 1003 may include a display and a keyboard, and the network interface 1004 may include a standard wired interface and a standard wireless interface (e.g., a Wi-Fi interface). The memory 1005 may be a high-speed random access memory (RAM), or may be a non-volatile memory, for example, at least one magnetic disk memory. In some embodiments, the memory 1005 may be at least one storage apparatus located remotely from the foregoing processor 1001. As shown in FIG. 13, the memory 1005 used as a computer storage medium may include an operating system, a network communication module, a user interface module, and a device control application program.

In the computer device 1000 shown in FIG. 13, the network interface 1004 may provide a network communication function. The user interface 1003 is mainly configured to provide an input interface for a user. The processor 1001 may be configured to invoke the device control application program stored in the memory 1005 to implement the following operations:
determining, in a driving simulation system, a sensing coverage region with sensing data and a sensing blank region not overlapping with the sensing coverage region in a simulated main road; the sensing blank region having no sensing data;
generating, at a simulation starting moment, a first virtual simulated vehicle in the sensing blank region according to a regional position relationship between the sensing coverage region and the sensing blank region;
in a simulation reproduction phase after the simulation starting moment, outputting, in the sensing coverage region, reproduced simulated driving behaviors of reproduced simulated vehicles corresponding to the sensing data, and outputting, in the sensing blank region according to an automatic driving model corresponding to the sensing blank region, virtual simulated driving behaviors of one or more second virtual simulated vehicles traveling in the sensing blank region; the one or more second virtual simulated vehicles including the first virtual simulated vehicle; and
in a simulation prediction phase after the simulation reproduction phase, outputting, on the simulated main road according to an automatic driving model corresponding to the simulated main road, a predicted simulated driving behavior of a third virtual simulated vehicle traveling on the simulated main road to obtain a predicted traffic state of the simulated main road, the predicted traffic state of the simulated main road being configured to control a traveling state of a physical vehicle traveling on a physical road corresponding to the simulated main road.

The computer device 1000 described in this embodiment of this application may perform the description of the data processing method or apparatus in the foregoing embodiments, which is not described herein again. In addition, the description of beneficial effects of the same method is not described herein again.

An embodiment of this application further provides a computer-readable storage medium. The computer-readable storage medium stores a computer program. After being executed by a processor, the computer program implements the description of the data processing method or apparatus in the foregoing embodiments, which is not described herein again. In addition, the description of beneficial effects of the same method is not described herein again.

The above computer-readable storage medium may be the data processing apparatus provided in any one of the foregoing embodiments or an internal storage unit of the foregoing computer device, for example, a hard disk or an internal memory of the computer device. The computer-readable storage medium may alternatively be an external storage device, for example, a plug-in hard disk, a smart media card (SMC), a secure digital (SD) card, or a flash card equipped on the computer device. Further, the computer-readable storage medium may further include both the internal storage unit and the external storage device of the computer device. The computer-readable storage medium is configured to store the computer program and other programs and data required by the computer device. The computer-readable storage medium may further be configured to temporarily store data that has been outputted or that is to be outputted.

An embodiment of this application further provides a computer program product. The computer program product includes a computer program. The computer program is stored in a computer-readable storage medium. A processor of a computer device reads the computer program from the computer-readable storage medium, and the processor executes the computer program, causing the computer device to perform the description of the data processing method or apparatus in the foregoing embodiments, which is not described herein again. In addition, the description of beneficial effects of the same method is not described herein again.

The terms “first,” “second,” and the like in the specification of the embodiments of this application, the claims, and the accompanying drawings are configured to distinguish different objects, rather than being configured to describe a specific sequence. In addition, the terms “include,” “have,” and any variation thereof are intended to cover a non-exclusive inclusion. For example, a process, method, apparatus, product, or device including a series of steps or units is not limited to the listed steps or modules, but further includes steps or modules not listed, or further includes other steps or units intrinsic to the process, method, apparatus, product, or device.

A person of ordinary skill in the art may understand that units and algorithm steps of the examples described in the foregoing disclosed embodiments may be implemented by electronic hardware, computer software, or a combination thereof. To clearly describe interchangeability between the hardware and the software, compositions and steps of each example have been generally described based on functions in the foregoing description. Whether the functions are executed by hardware or software depends on particular applications and design constraint conditions of the technical solutions. A person skilled in the art may use different methods to implement the described functions for each particular application, but it is not considered that the implementation goes beyond the scope of this application.

Disclosed above are merely exemplary embodiments of this application, which are certainly not intended to limit the scope of the claims of this application. Therefore, equivalent variations made in accordance with the claims of this application shall fall within the scope of this application.

What is claimed is:

1. A data processing method, performed by a computer device running a driving simulation system and comprising:
determining, in the driving simulation system, a sensing coverage region with sensing data and a sensing blank region not overlapping with the sensing coverage region in a simulated road;
generating, at a simulation starting moment, a first virtual simulated vehicle in the sensing blank region according to a regional position relationship between the sensing coverage region and the sensing blank region;
in a simulation reproduction phase after the simulation starting moment, outputting, in the sensing coverage region, reproduced simulated driving behaviors of one or more reproduced simulated vehicles corresponding to the sensing data, and outputting, in the sensing blank region according to an automatic driving model corresponding to the sensing blank region, virtual simulated driving behaviors of one or more second virtual simulated vehicles traveling in the sensing blank region, the one or more second virtual simulated vehicles including the first virtual simulated vehicle; and
in a simulation prediction phase after the simulation reproduction phase, outputting, on the simulated road according to an automatic driving model corresponding to the simulated road, predicted simulated driving behaviors of one or more third virtual simulated vehicles traveling on the simulated road to obtain a predicted traffic state of the simulated road.

2. The method according to claim 1,
wherein generating the first virtual simulated vehicle includes:
determining a starting traffic state corresponding to the sensing blank region according to the regional position relationship between the sensing coverage region and the sensing blank region, the starting traffic state including starting vehicle density, starting vehicle flow, and a starting vehicle speed; and
generating the first virtual simulated vehicle according to the starting traffic state;
the method further comprising:
obtaining, from the sensing data, starting sensing data of the sensing coverage region at the simulation starting moment; and
generating one or more starting reproduced simulated vehicles in the sensing coverage region according to the starting sensing data, each of the one or more starting reproduced simulated vehicles being one of the one or more reproduced simulated vehicles corresponding to the reproduced simulated driving behaviors.

3. The method according to claim 2, wherein:
the sensing coverage region is one of P sensing coverage regions, P being a positive integer; and
determining the starting traffic state includes:
obtaining, from the P sensing coverage regions, a target sensing coverage region contiguous with the sensing blank region and downstream of the sensing blank region in response to a regional position relationship between the P sensing coverage regions and the sensing blank region is:
an upstream regional relationship, which represents that the sensing blank region is located in an upstream region of all the P sensing coverage regions, or
a midstream regional relationship, which represents that the sensing blank region is located between two of the P sensing coverage regions;
obtaining, from starting sensing data corresponding to the P sensing coverage regions, target starting sensing data corresponding to the target sensing coverage region;
determining the starting traffic state according to the target starting sensing data in response to the target starting sensing data meeting a state setting condition for the sensing blank region; and
obtaining historical data of the sensing blank region and determining the starting traffic state according to the historical data, in response to the target starting sensing data not meeting the state setting condition.

4. The method according to claim 3, further comprising:
determining that the target starting sensing data meets the state setting condition in response to the one or more starting reproduced simulated vehicles including two or more starting reproduced simulated vehicles and at least two of the two or more starting reproduced simulated vehicles being in one of one or more simulated lanes in the target sensing coverage region; and
determining that the target starting sensing data does not meet the state setting condition in response to none of the one or more simulated lanes having more than one of the one or more starting reproduced simulated vehicles.

5. The method according to claim 3, wherein determining the starting traffic state according to the target starting sensing data includes:
determining, for each of one or more simulated lanes in the target sensing coverage region, an average inter-vehicle distance corresponding to the simulated lane;
determining a vehicle density corresponding to the sensing blank region according to the average inter-vehicle distance of each of the one or more simulated lanes in the target sensing coverage region; and
determining the starting traffic state according to the vehicle density and a basic traffic map corresponding to the target sensing coverage region.

6. The method according to claim 3, wherein determining the starting traffic state according to the historical data includes:
obtaining starting historical data corresponding to the simulation starting moment from the historical data and determining the starting historical data to be the starting traffic state, in response to the historical data being not a null set; and
determining the starting traffic state according to a target traffic state in a basic traffic map corresponding to the sensing blank region in response to the historical data being a null set.

7. The method according to claim 2, wherein:
the sensing coverage region is one of M sensing coverage regions, M being a positive integer; and
determining the starting traffic state includes:
obtaining historical data of the sensing blank region in response to a regional position relationship between the M sensing coverage regions and the sensing blank region being a downstream regional relationship, which represents that the sensing blank region is located in a downstream region of all the M sensing coverage regions;
obtaining starting historical data corresponding to the simulation starting moment from the historical data and determining the starting historical data to be the starting traffic state, in response to the historical data being not a null set; and
obtaining, from the M sensing coverage regions, an upstream sensing coverage region contiguous with the sensing blank region and upstream of the sensing blank region and determining the starting traffic state according to the upstream sensing coverage region, in response to the historical data being a null set.

8. The method according to claim 7, wherein determining the starting traffic state according to the upstream sensing coverage region includes:
obtaining, from the starting sensing data, target starting sensing data corresponding to the upstream sensing coverage region;
determining the starting traffic state according to the target starting sensing data in response to the target starting sensing data meeting a state setting condition for the sensing blank region; and
determining the starting traffic state according to a target traffic state in a basic traffic map corresponding to the sensing blank region in response to the target starting sensing data not meeting the state setting condition.

9. The method according to claim 2, wherein generating the first virtual simulated vehicle according to the starting traffic state includes:
determining an average inter-vehicle distance corresponding to the sensing blank region according to the starting traffic state;
generating the first virtual simulated vehicle along a direction opposite to a traveling direction of the simulated road according to the average inter-vehicle distance and a downstream edge of the sensing blank region, in response to the regional position relationship being:
an upstream regional relationship, which represents that the sensing coverage region is one of one or more sensing coverage regions and the sensing blank region is located in an upstream region of all of the one or more sensing coverage regions, or
a midstream regional relationship, which represents that the sensing coverage region is one of at least two sensing coverage regions and the sensing blank region is located between two of the at least two sensing coverage regions; and
generating the first virtual simulated vehicle along the traveling direction according to the average inter-vehicle distance and an upstream edge of the sensing blank region, in response to the regional position relationship being a downstream regional relationship, which represents that the sensing coverage region is one of one or more sensing coverage regions and the sensing blank region is located in a downstream region of all of the one or more sensing coverage regions.

10. The method according to claim 1, wherein:
the regional position relationship is an upstream regional relationship, which represents that the sensing coverage region is one of one or more sensing coverage regions and the sensing blank region is located in an upstream region of all of the one or more sensing coverage regions; and
outputting the virtual simulated driving behaviors of the one or more second virtual simulated vehicles includes:
obtaining, from the sensing data, downstream sensing data corresponding to a target sensing coverage region, the target sensing coverage region being one of the one or more sensing coverage regions that is contiguous with the sensing blank region and downstream of the sensing blank region;
generating a fourth virtual simulated vehicle in a vehicle generation sub-region of the sensing blank region according to the downstream sensing data, the vehicle generation sub-region being located at an upstream edge of the sensing blank region;
determining each of the first virtual simulated vehicle and the fourth virtual simulated vehicle to be one of the one or more second virtual simulated vehicles; and
outputting the virtual simulated driving behaviors of the one or more second virtual simulated vehicles in the sensing blank region according to the automatic driving model corresponding to the sensing blank region and a vehicle removal line, the vehicle removal line being located in a downstream region of the vehicle generation sub-region in the sensing blank region and configured to instruct the driving simulation system to remove, from the driving simulation system, any of the one or more second virtual simulated vehicles that has traveled to the vehicle removal line.

11. The method according to claim 10, further comprising:
obtaining an initial automatic driving model corresponding to the sensing blank region, and obtaining historical data of the sensing blank region;
adjusting, according to the historical data, parameters in the initial automatic driving model to obtain the automatic driving model corresponding to the sensing blank region, in response to the historical data being not a null set; and
adjusting, according to a road type corresponding to the sensing blank region, the parameters in the initial automatic driving model corresponding to the sensing blank region to obtain the automatic driving model corresponding to the sensing blank region, in response to the historical data being a null set.

12. The method according to claim 10, further comprising:
determining one of the one or more second virtual simulated vehicles that is closest to a downstream edge of the sensing blank region to be a first vehicle in the sensing blank region;
determining a maximum vehicle speed of the first vehicle according to the downstream sensing data;
determining an upstream vehicle from the one or more second virtual simulated vehicles, the upstream vehicle being not the first vehicle;
determining a maximum vehicle speed of the upstream vehicle according to a road type corresponding to the sensing blank region; and
outputting the virtual simulated driving behaviors of the one or more second virtual simulated vehicles in the sensing blank region according to the automatic driving model corresponding to the sensing blank region and the vehicle removal line includes:
outputting the virtual simulated driving behaviors of the one or more second virtual simulated vehicles in the sensing blank region according to the automatic driving model corresponding to the sensing blank region, the vehicle removal line, the maximum vehicle speed of the upstream vehicle, and the maximum vehicle speed of the first vehicle.

13. The method according to claim 12, wherein:
the upstream vehicle is a first upstream vehicle; and
determining the maximum vehicle speed of the first vehicle according to the downstream sensing data includes:
determining, in response to the downstream sensing data indicating that at least one reproduced simulated vehicle of the one or more reproduced simulated vehicles exists in the target sensing coverage region, one of the at least one reproduced simulated vehicle in the target sensing coverage region that is closest to an upstream edge of the target sensing coverage region to be a second upstream vehicle;
determining a vehicle speed of the second upstream vehicle to be the maximum vehicle speed of the first vehicle;
obtaining, in response to the downstream sensing data indicating that none of the one or more reproduced simulated vehicles exists in the target sensing coverage region and historical data of the sensing blank region is not a null set, a historical vehicle speed from the historical data, and determining the historical vehicle speed to be the maximum vehicle speed of the first vehicle; and
determining, in response to the downstream sensing data indicating that none of the one or more reproduced simulated vehicles exists in the target sensing coverage region and the historical data of the sensing blank region is a null set, the maximum vehicle speed of the first vehicle according to the road type.

14. The method according to claim 1, wherein:
the regional position relationship is a midstream regional relationship, which represents that the sensing coverage region is one of at least two sensing coverage regions and the sensing blank region is located between two of the at least two sensing coverage regions; and
outputting the virtual simulated driving behaviors of the one or more second virtual simulated vehicles includes:
determining a fourth virtual simulated vehicle, the fourth virtual simulated vehicle being one of the one or more reproduced simulated vehicles that was in a target sensing coverage region but has traveled to the sensing blank region, the target sensing coverage region being one of the at least two sensing coverage regions that is contiguous with the sensing blank region and downstream of the sensing blank region;
determining each of the first virtual simulated vehicle and the fourth virtual simulated vehicle to be one of the one or more second virtual simulated vehicles; and
outputting the virtual simulated driving behaviors of the one or more second virtual simulated vehicles in the sensing blank region according to the automatic driving model corresponding to the sensing blank region and a vehicle removal line, the vehicle removal line being located in the sensing blank region and configured to instruct the driving simulation system to remove, from the driving simulation system, any of the one or more second virtual simulated vehicles that has traveled to the vehicle removal line.

15. The method according to claim 1, wherein:
the regional position relationship is a downstream regional relationship, which represents that the sensing coverage region is one of one or more sensing coverage regions and the sensing blank region is located in a downstream region of all of the one or more sensing coverage regions; and
outputting the virtual simulated driving behaviors of the one or more second virtual simulated vehicles includes:
determining a fourth virtual simulated vehicle, the fourth virtual simulated vehicle being one of the one or more reproduced simulated vehicles that was in an upstream sensing coverage region but has traveled to the sensing blank region, the upstream sensing coverage region being one of the one or more sensing coverage regions that is contiguous with the sensing blank region and upstream of the sensing blank region;
determining each of the first virtual simulated vehicle and the fourth virtual simulated vehicle to be one of the one or more second virtual simulated vehicles; and
outputting the virtual simulated driving behaviors of the one or more second virtual simulated vehicles in the sensing blank region according to the automatic driving model corresponding to the sensing blank region and a downstream edge of the sensing blank region, the downstream edge of the sensing blank region being configured to instruct the driving simulation system to remove, from the driving simulation system, any of the one or more second virtual simulated vehicles that has traveled to the downstream edge of the sensing blank region.

16. The method according to claim 1, wherein outputting the predicted simulated driving behaviors of the one or more third virtual simulated vehicle includes:
determining one or more fourth virtual simulated vehicles, each of the one or more fourth virtual simulated vehicles being one of the one or more second virtual simulated vehicles that has not been removed from the driving simulation system at the end of the simulation reproduction phase;
determining one or more target reproduced simulated vehicles, each of the one or more target reproduced simulated vehicles being one of the one or more reproduced simulated vehicles that has not been removed from the driving simulation system at the end of the simulation reproduction phase;
generating, according to historical data in a sensing region to which a vehicle generation sub-region in the simulated road belongs, one or more fifth virtual simulated vehicles in the vehicle generation sub-region, the vehicle generation sub-region being located at an upstream edge of the simulated road, and the sensing region to which the vehicle generation sub-region belongs belonging to the sensing coverage region or the sensing blank region;
determining each of the one or more fourth virtual simulated vehicles, the one or more target reproduced simulated vehicles, and the one or more fifth virtual simulated vehicles to be one of the one or more third virtual simulated vehicles; and
outputting, according to the automatic driving model corresponding to the simulated road and a downstream edge of the simulated road, the predicted simulated driving behaviors of the one or more third virtual simulated vehicles on the simulated road, the downstream edge of the simulated road being configured to instruct the driving simulation system to remove, from the driving simulation system, any of the one or more third virtual simulated vehicles that has traveled to the downstream edge of the simulated road.

17. A computer device comprising:
at least one processor; and
at least one memory storing at least one computer program that, when executed by the at least one processor, causes the computer device to:
determine, in a driving simulation system, a sensing coverage region with sensing data and a sensing blank region not overlapping with the sensing coverage region in a simulated road;
generate, at a simulation starting moment, a first virtual simulated vehicle in the sensing blank region according to a regional position relationship between the sensing coverage region and the sensing blank region;
in a simulation reproduction phase after the simulation starting moment, output, in the sensing coverage region, reproduced simulated driving behaviors of one or more reproduced simulated vehicles corresponding to the sensing data, and output, in the sensing blank region according to an automatic driving model corresponding to the sensing blank region, virtual simulated driving behaviors of one or more second virtual simulated vehicles traveling in the sensing blank region, the one or more second virtual simulated vehicles including the first virtual simulated vehicle; and
in a simulation prediction phase after the simulation reproduction phase, output, on the simulated road according to an automatic driving model corresponding to the simulated road, predicted simulated driving behaviors of one or more third virtual simulated vehicles traveling on the simulated road to obtain a predicted traffic state of the simulated road.

18. The computer device according to claim 17, wherein the at least one computer program, when executed by the at least one processor, further causes the computer device to:
determine a starting traffic state corresponding to the sensing blank region according to the regional position relationship between the sensing coverage region and the sensing blank region, the starting traffic state including starting vehicle density, starting vehicle flow, and a starting vehicle speed; and
generate the first virtual simulated vehicle according to the starting traffic state;
obtain, from the sensing data, starting sensing data of the sensing coverage region at the simulation starting moment; and
generate one or more starting reproduced simulated vehicles in the sensing coverage region according to the starting sensing data, each of the one or more starting reproduced simulated vehicles being one of the one or more reproduced simulated vehicles corresponding to the reproduced simulated driving behaviors.

19. The computer device according to claim 18, wherein:
the sensing coverage region is one of P sensing coverage regions, P being a positive integer; and
the at least one computer program, when executed by the at least one processor, further causes the computer device to:
obtain, from the P sensing coverage regions, a target sensing coverage region contiguous with the sensing blank region and downstream of the sensing blank region in response to a regional position relationship between the P sensing coverage regions and the sensing blank region is:
an upstream regional relationship, which represents that the sensing blank region is located in an upstream region of all the P sensing coverage regions, or
a midstream regional relationship, which represents that the sensing blank region is located between two of the P sensing coverage regions;
obtain, from starting sensing data corresponding to the P sensing coverage regions, target starting sensing data corresponding to the target sensing coverage region;
determine the starting traffic state according to the target starting sensing data in response to the target starting sensing data meeting a state setting condition for the sensing blank region; and
obtain historical data of the sensing blank region and determining the starting traffic state according to the historical data, in response to the target starting sensing data not meeting the state setting condition.

20. A non-transitory computer-readable storage medium storing at least one computer program that, when executed by at least one processor, causes the at least one processor to:
determine, in a driving simulation system, a sensing coverage region with sensing data and a sensing blank region not overlapping with the sensing coverage region in a simulated road;
generate, at a simulation starting moment, a first virtual simulated vehicle in the sensing blank region according to a regional position relationship between the sensing coverage region and the sensing blank region;
in a simulation reproduction phase after the simulation starting moment, output, in the sensing coverage region, reproduced simulated driving behaviors of one or more reproduced simulated vehicles corresponding to the sensing data, and output, in the sensing blank region according to an automatic driving model corresponding to the sensing blank region, virtual simulated driving behaviors of one or more second virtual simulated vehicles traveling in the sensing blank region, the one or more second virtual simulated vehicles including the first virtual simulated vehicle; and
in a simulation prediction phase after the simulation reproduction phase, output, on the simulated road according to an automatic driving model corresponding to the simulated road, predicted simulated driving behaviors of one or more third virtual simulated vehicles traveling on the simulated road to obtain a predicted traffic state of the simulated road.
